(19) United States
(12) Patent Application Publication
(10) Pub. No.: US 2023/0246134 A1
(43) Pub. Date: Aug. 3, 2023

(54) LIGHT EMITTING ELEMENT AND DISPLAY DEVICE INCLUDING THE SAME

(71) Applicant: Samsung Display Co., LTD., Yongin-si, Gyeonggi-do (KR)

(72) Inventors: Jong Chan LEE, Suwon-si, Gyeonggi-do (KR); Hyun KIM, Seoul (KR); Sung Jin LEE, Yongin-si, Gyeonggi-do (KR); Jeong Hyun LEE, Asan-si, Chungcheongnam-do (KR); Tae Hee LEE, Asan-si, Chungcheongnam-do (KR); Seung Jin CHU, Gwangmyeong-si, Gyeonggi-do (KR)

(73) Assignee: Samsung Display Co., LTD., Yongin-si, Gyeonggi-do (KR)

(21) Appl. No.: 17/926,242

(22) PCT Filed: Aug. 11, 2020
(86) PCT No.: PCT/KR2020/010621

§ 371 Date: Nov. 18, 2022

(30) Foreign Application Priority Data
May 20, 2020 (KR) 10-2020-0060212

(51) Int. Cl. H01L 33/38; H01L 33/62; H01L 25/075; H01L 33/20

(52) U.S. Cl. CPC H01L 33/382; H01L 33/62; H01L 25/0753; H01L 33/20

(57) ABSTRACT

The display device includes: a substrate; a first electrode and a second electrode that are disposed on the substrate and spaced apart from each other; a first insulating layer disposed between the first electrode and the second electrode and covering the first electrode and the second electrode; and a light emitting element disposed on the first insulating layer and extending in a first direction. The light emitting element includes: a first side extending in the first direction; a second side opposite to the first side; a first lateral side connecting first end portions of the first and second sides; and a second lateral side connecting second end portions of the first and second sides. Each of a first interior angle and a second interior angle, which are formed by the first side and the first and second lateral sides, is an acute angle.

### CROSS REFERENCE TO RELATED APPLICATION(S)

This application is a national entry of International Application No. PCT/KR2020/010621, filed on Aug. 11, 2020, which claims under 35 U.S.C. §§ 119(a) and 365(b) priority to and benefits of Korean Patent Application No. 10-2020-0060212, filed on May 20, 2020, in the Korean Intellectual Property Office (KIPO), the entire content of which are incorporated herein by reference.

### BACKGROUND

### 1. Technical Field

Embodiments relate to a light emitting element and a display device including the light emitting element.

### 2. Description of the Related Art

The importance of display devices has steadily increased with the development of multimedia technology. Various types of display devices such as an organic light emitting display (OLED), a liquid crystal display (LCD) and the like have been used in various fields.

A display device is a device for displaying an image, and includes a display panel, such as an organic light emitting display panel or a liquid crystal display panel. The light emitting display panel may include light emitting elements, e.g., light emitting diodes (LED), and examples of the light emitting diode include an organic light emitting diode (OLED) formed of an organic material as a fluorescent material and an inorganic light emitting diode formed of an inorganic material as a fluorescent material.

### SUMMARY

Embodiments provide a display device capable of improving contact reliability between a contact electrode and a light emitting element by forming end portions (e.g., opposite end portions) of the light emitting element to be inclined to prevent an insulating material from remaining in areas adjacent to the light emitting element.

Embodiments also provide a display device capable of improving contact reliability by forming end portions (e.g., opposite end portions) of a light emitting element having the same width to be inclined to increase a contact area between a contact electrode and the light emitting element.

However, embodiments of the disclosure are not limited to those set forth herein. The above and other embodiments will become more apparent to one of ordinary skill in the art to which the disclosure pertains by referencing the detailed description of the disclosure given below.

According to an embodiment, a display device may include a substrate, a first electrode disposed on the substrate, a second electrode disposed on the substrate and spaced apart from the first electrode, a first insulating layer disposed between the first electrode and the second electrode and covering at least a portion of the first electrode and the second electrode, and a light emitting element disposed on the first insulating layer between the first electrode and the second electrode and extending in a first direction, wherein the light emitting element may include a first side extending in the first direction, a second side extending in the first direction and opposite to the first side, a first lateral side connecting a first end portion of the first side and a first end portion of the second side to each other, and a second lateral side connecting a second end portion of the first side and a second end portion of the second side to each other, a first interior angle formed by the first side and the first lateral side is an acute angle, and a second interior angle formed by the first side and the second lateral side is an acute angle.

The first interior angle may be about 75° or less, and the second interior angle may be about 75° or less.

The the first interior angle and the second interior angle may be substantially equal to each other.

The light emitting element may include a semiconductor core extending in the first direction, and an insulating layer surrounding a side surface of the semiconductor core.

The semiconductor core may include a first semiconductor layer, a second semiconductor layer disposed on the first semiconductor layer, and an active layer disposed between the first semiconductor layer and the second semiconductor layer.

The first semiconductor layer, the active layer, and the second semiconductor layer may be sequentially disposed in the first direction, and each boundary surface between the first semiconductor layer, the active layer, and the second semiconductor layer may be substantially perpendicular to the first direction.

The first semiconductor layer, the active layer, and the second semiconductor layer may be sequentially disposed in the first direction, and each boundary surface between the first semiconductor layer, the active layer, and the second semiconductor layer may be inclined with respect to the first direction.

The first side of the light emitting element may be at least partially in contact with an upper surface of the first insulating layer.

The upper surface of the first insulating layer in contact with the light emitting element and the first side of the light emitting element may be inclined at an acute angle, and the upper surface of the first insulating layer in contact with the light emitting element and the second side of the light emitting element may be inclined at an acute angle of inclination.

The display device may further include a second insulating layer disposed on the light emitting element and exposing the first lateral side of the light emitting element and the second lateral side of the light emitting element.

The second insulating layer may do not overlap the first lateral side of the light emitting element and the second lateral side of the light emitting element.

The display device may further include a first contact electrode and a second contact electrode disposed on the first insulating layer and spaced apart from each other, wherein the first contact electrode may be in contact with the first electrode and the first lateral side of the light emitting element, and the second contact electrode may be in contact with the second electrode and the second lateral side of the light emitting element.

According to an embodiment, a display device may include a substrate, a first electrode disposed on the substrate, a second electrode disposed on the substrate and spaced apart from the first electrode, a first insulating layer disposed between the first electrode and the second electrode and covering at least a portion of the first electrode and the second electrode, and a light emitting element disposed on the first insulating layer between the first electrode and the second electrode and extending in a first direction, wherein the light emitting element includes a first end portion electrically connected to the first electrode, and a second end portion electrically connected to the second electrode, the first end portion and the second end portion are inclined with respect to the first direction.

The first direction may be substantially parallel to an upper surface of the substrate, an inclined surface of the first end portion of the light emitting element may be inclined in a first diagonal direction with respect to the upper surface of the substrate, an inclined surface of the second end portion of the light emitting element may be inclined in a second diagonal direction with respect to the upper surface of the substrate, and the directions in which the inclined surface of the first end portion of the light emitting element and the inclined surface of the second end portion of the light emitting element may be inclined with respect to the upper surface of the substrate are opposite to each other.

The inclined surface of the first end portion of the light emitting element and the inclined surface of the second end portion of the light emitting element may be in a symmetrical relationship with respect to a cut surface crossing a central portion of the light emitting element in a direction perpendicular to the first direction.

The display device may further include a first contact electrode and a second contact electrode disposed on the first insulating layer and spaced apart from each other, wherein the first contact electrode may be in contact with the first electrode and the first end portion of the light emitting element, and the second contact electrode may be in contact with the second electrode and the second end portion of the light emitting element.

The display device may further include a second insulating layer disposed on the light emitting element and not overlapping the first end portion of the light emitting element and the second end portion of the light emitting element.

An inclined extension surface of the first end portion of the light emitting element and an inclined extension surface of the second end portion of the light emitting element may be each inclined to be closer to each other as moving in a second direction perpendicular to the first direction in a central portion of the light emitting element.

The second direction may be a thickness direction of the display device.

According to an embodiment, a light emitting element may include a first side extending in a first direction, a second side extending in the first direction and opposite to the first side, a first lateral side connecting a first end portion of the first side and a first end portion of the second side to each other, and a second lateral side connecting a second end portion of the first side and a second end portion of the second side to each other, a first interior angle formed by the first side and the first lateral side may be an acute angle, and a second interior angle formed by the first side and the second lateral side may be an acute angle.

The light emitting element may include a semiconductor core extending in the first direction, and an insulating layer surrounding a side surface of the semiconductor core.

The semiconductor core may include a first semiconductor layer, a second semiconductor layer disposed on the first semiconductor layer, and an active layer disposed between the first semiconductor layer and the second semiconductor layer.

The first semiconductor layer, the active layer, and the second semiconductor layer may be sequentially disposed in the first direction, and each boundary surface between the first semiconductor layer, the active layer, and the second semiconductor layer may be substantially perpendicular to the first direction.

The first semiconductor layer, the active layer, and the second semiconductor layer may be sequentially disposed in the first direction, and each boundary surface between the first semiconductor layer, the active layer, and the second semiconductor layer may be inclined with respect to the first direction.

The details of other embodiments are included in the detailed description and the accompanying drawings.

In the display device according to an embodiment, it is possible to prevent a residual film of a second insulating material layer from being generated in areas adjacent to the light emitting element in a process of patterning a second insulating layer by forming end portions (e.g., opposite end portions) of the light emitting element to be inclined. Accordingly, a poor contact between the light emitting element and a contact electrode may be prevented by preventing the second insulating material layer from remaining in areas adjacent to end portions (e.g., opposite end portions) of the light emitting element.

It is possible to provide a display device having improved contact reliability by forming end portions (e.g., opposite end portions) of the light emitting element to be inclined to increase a contact area with the contact electrode for the same width of the light emitting element.

The effects according to the embodiments are not limited by the contents described as examples above, and more various effects are included in this disclosure.

### BRIEF DESCRIPTION OF DRAWINGS

FIG. 1 is a schematic plan view of a display device according to an embodiment;

FIG. 2 is a schematic plan view illustrating a pixel of the display device according to an embodiment;

FIG. 3 is a schematic cross-sectional view taken along lines IIIa-IIIa′, IIIb-IIIb′, and IIIc-IIIc′ of FIG. 2;

FIG. 4 is a partial schematic cross-sectional view of the display device according to an embodiment:

FIG. 5 is a schematic perspective view of a light emitting element according to an embodiment;

FIG. 6 is a schematic side view of the light emitting element of FIG. 5;

FIG. 7 is a schematic enlarged cross-sectional view of area P of FIG. 3;

FIG. 8A is a schematic cross-sectional view illustrating an example of the light emitting element taken along line VIII-VIII′ of FIG. 5;

FIG. 8B is a schematic cross-sectional view illustrating another example of a light emitting element taken along the line VIII-VIII′ of FIG. 5;

FIG. 8C is a schematic cross-sectional view illustrating another example of a light emitting element taken along the line VIII-VIII′ of FIG. 5;

FIG. 9 is a schematic enlarged cross-sectional view of area Q of FIG. 3 in which the light emitting element of FIG. 8A is disposed;

FIGS. 10 to 16 are schematic cross-sectional views illustrating a process of manufacturing the light emitting element of FIG. 8A;

FIG. 17 is a schematic cross-sectional view illustrating another example of the light emitting element taken along the line VIII-VIII′ of FIG. 5;

FIG. 18 is a schematic enlarged cross-sectional view of area Q of FIG. 3 in which the light emitting element of FIG. 17 is disposed; and

FIGS. 19 to 23 are schematic cross-sectional views illustrating processes of manufacturing the light emitting element of FIG. 17.

### DETAILED DESCRIPTION OF THE EMBODIMENTS

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the invention.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the DR1-axis, the DR2-axis, and the DR3-axis are not limited to three axes of a rectangular coordinate system, such as the X, Y, and Z-axes, and may be interpreted in a broader sense. For example, the DR1-axis, the DR2-axis, and the DR3-axis may be perpendicular to one another, or may represent different directions that are not perpendicular to one another. Further, the X-axis, the Y-axis, and the Z-axis are not limited to three axes of a rectangular coordinate system, such as the x, y, and z axes, and may be interpreted in a broader sense. For example, the X-axis, the Y-axis, and the Z-axis may be perpendicular to one another, or may represent different directions that are not perpendicular to one another. For the purposes of this disclosure, “at least one of A and B” may be construed as understood to mean A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the invention. For example, the second element could also be termed the first element.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing In this manner, regions illustrated in the drawings may be schematic in nature and the shapes of these regions may not reflect actual shapes of regions of a device and, as such, are not necessarily intended to be limiting.

Hereinafter, embodiments will be described with reference to the accompanying drawings.

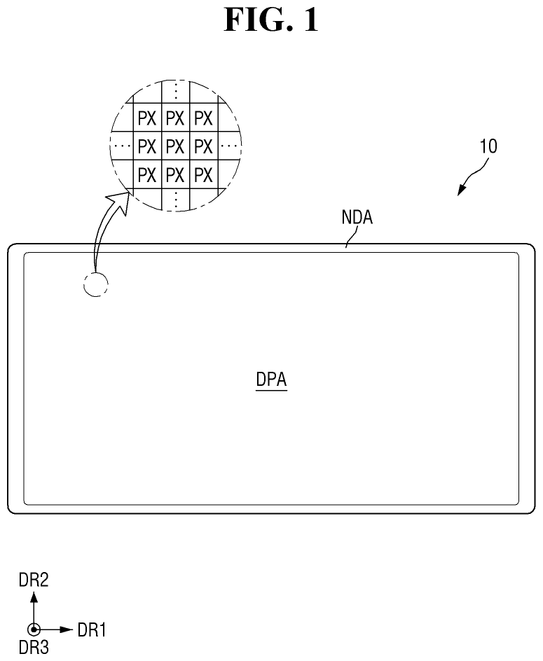

FIG. 1 is a schematic plan view of a display device according to an embodiment.

Referring to FIG. 1, a display device 10 may display a mobile image or a still image. The display device 10 may refer to any electronic device that provides a display screen. For example, the display device 10 may include televisions, laptop computers, monitors, billboards, internet of things devices, mobile phones, smartphones, tablet personal computers (PCs), electronic watches, smartwatches, watch phones, head mounted displays, mobile communication terminals, electronic notebooks, electronic books, portable multimedia players (PMPs), navigation system, game consoles, digital cameras, camcorders, and the like.

The display device 10 may include a display panel with a display screen. Examples of the display panel may include an inorganic light emitting diode display panel, an organic light emitting display panel, a quantum dot light emitting display panel, a plasma display panel, and a field emission display panel. Hereinafter, an inorganic light emitting diode display panel may be described as an example of the display panel, but embodiments are not limited thereto. Any display panel may be applied as the display panel as long as the same technical idea is applicable.

In the drawings, a first direction DR1, a second direction DR2, and a third direction DR3 are defined. The first direction DR1 and the second direction DR2 may be directions perpendicular to each other in a plane. The third direction DR3 may be a direction perpendicular to the plane in which the first direction DR1 and the second direction DR2 are positioned. The third direction DR3 is perpendicular to each of the first direction DR1 and the second direction DR2. In embodiments, the third direction DR3 refers to a thickness direction of the display device 10.

The display device 10 may have a rectangular shape including a long side and a short side in which the first direction DR1 is longer than the second direction DR2 in a plan view. A corner portion where the long side and the short side of the display device 10 meet in a plan view may be a right angle, and may also have a rounded curved shape. However, embodiments are not limited thereto. The shape of the display device 10 is not limited to those described above, and may be variously modified. For example, the display device 10 may also have other shapes such as a square, a rectangle having rounded corners (e.g., vertexes), another polygon, and a circle.

A display surface of the display device 10 may be disposed on a side in the third direction DR3, which is the thickness direction. In the description, unless otherwise stated in the embodiments, an upper portion or an upper side refers a side facing toward the third direction DR3 (e.g., a display direction), and an upper surface refers a surface facing toward the third direction DR3. For example, a lower portion or a lower side refers a side facing toward a direction opposite to in the third direction DR3 (e.g., the display direction), and a lower surface refers to a surface facing toward the third direction DR3.

The display device 10 may include a display area DPA and a non-display area NDA. The display area DPA may be an area in which a screen may be displayed, and the non-display area NDA may be an area in which a screen is not displayed. The display area DPA may be referred to as an active area, and the non-display area NDA may be referred to as a non-active area.

A shape of the display area DPA may correspond to the shape of the display device 10. For example, the shape of the display area DPA may have a rectangular shape in a plan view, similar to an overall shape of the display device 10. The display area DPA may occupy the center area of the display device 10.

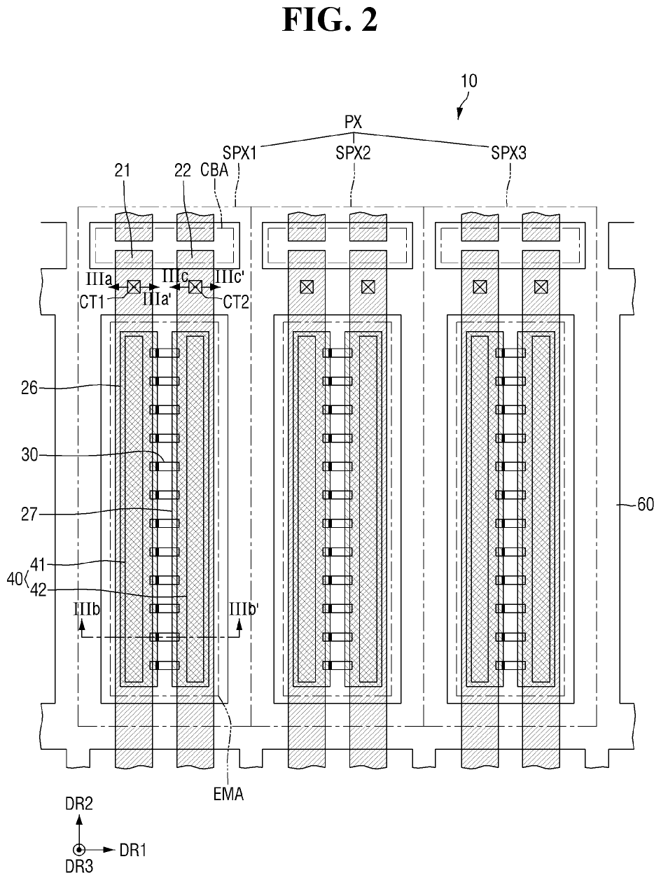

The display area DPA may include pixels PX. The pixels PX may be arranged in a matrix form. Each of the pixels PX may have a rectangular shape or a square shape in a plan view. However, embodiments are not limited thereto, and each of the pixels PX may have a rhombic shape in which each side is inclined with respect to a direction. The respective pixels PX may be alternately arranged in a stripe form or a PENTILE® form. For example, each of the pixels PX may include one or more light emitting elements 30 (see FIG. 2) emitting light of a specific wavelength band.

The non-display area NDA may be disposed around the display area DPA. The non-display area NDA may entirely or partially surround the display area DPA. In an embodiment, the display area DPA may have a rectangular shape, and the non-display area NDA may be disposed adjacent to four sides of the display area DPA. The non-display area NDA may form a bezel of the display device 10. Wirings or circuit drivers included in the display device 10 may be disposed in the non-display area NDA, or a pad portion on which an external device is mounted may be disposed therein.

FIG. 2 is a schematic plan view illustrating a pixel of the display device according to an embodiment.

Referring to FIG. 2, each of the pixels PX may include sub-pixels SPX (e.g., SPX1, SPX2, and SPX3). For example, a pixel PX may include a first sub-pixel SPX1, a second sub-pixel SPX2, and a third sub-pixel SPX3. The first sub-pixel SPX1 may emit light of a first color, the second sub-pixel SPX2 may emit light of a second color, and the third sub-pixel SPX3 may emit light of a third color. The first color may be blue, the second color may be green, and the third color may be red. However, embodiments are not limited thereto, and each of the sub-pixels SPX1, SPX2, and SPX3 may emit light of the same color. Although FIG. 2 illustrates that each pixel PX includes three sub-pixels SPX1, SPX2, and SPX3, embodiments are not limited thereto, and each pixel PX may include a larger number of sub-pixels SPX.

Each of the sub-pixels SPX of the display device 10 may include a light emitting area EMA and a non-light emitting area. The light emitting area EMA may be an area from which the light emitted from the light emitting element 30 is emitted, and the non-light emitting area may be an area where light emitted from the light emitting element does not reach so that no light is emitted therefrom.

The light emitting area EMA may include an area in which the light emitting element 30 is disposed and an area adjacent thereto. For example, the light emitting area may further include an area in which the light emitted from the light emitting element 30 is reflected or refracted by another member and emitted.

Each of the sub-pixels SPX may further include a cut area CBA disposed in the non-light emitting area. The cut area CBA may be disposed at a side of the light emitting area EMA in a second direction DR2. The cut area CBA may be disposed between the light emitting areas EMA of the sub-pixel SPX adjacent to each other in the second direction DR2.

The light emitting areas EMA of the respective sub-pixels SPX included in a pixel PX may be arranged to be spaced apart from each other in the first direction DR1. For example, cut areas CBA may be arranged to be spaced apart from each other in the first direction DR1. The light emitting areas EMA and the cut areas CBA are arranged to be spaced apart from each other in the first direction DR1, respectively, and may be alternately arranged in the second direction DR2.

The cut area CBA may be an area in which electrodes 21 and 22 included in each sub-pixel SPX adjacent to each other in the second direction DR2 are separated from each other. The light emitting element 30 may not be disposed in the cut area CBA. For example, a portion of the electrodes 21 and 22 disposed in each of the sub-pixels SPX may be disposed in the cut area CBA. The electrodes 21 and 22 disposed in each of the sub-pixels SPX may be separated from each other in the cut area CBA.

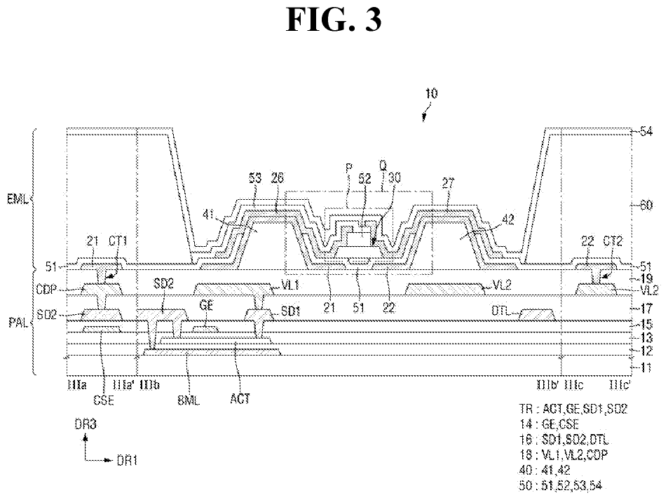

FIG. 3 is a schematic cross-sectional view taken along lines IIIa-IIIa′, IIIb-IIIb′, and IIIc-IIIc′ of FIG. 2.

Referring to FIG. 3, the display device 10 may include a circuit element layer PAL and a light emitting layer EML disposed on the circuit element layer PAL. The circuit element layer PAL may include a substrate 11, and a buffer layer 12, a lower metal layer BML, a semiconductor layer, conductive layers, insulating layers, a via layer 19, and the like, which are disposed on the substrate 11. The light emitting layer EML may be disposed on the via layer 19 of the circuit element layer PAL, and may include electrodes 21 and 22, a wall 40, a light emitting element 30, insulating layers 51, 52, 53, and 54, and a bank 60.

The substrate 11 may be an insulating substrate. The substrate 11 may be made of an insulating material such as glass, quartz, or a polymer resin. For example, the substrate 11 may be a rigid substrate. In another example, the substrate 11 may also be a flexible substrate capable of bending, folding, rolling, or the like.

The lower metal layer BML may be disposed on the substrate 11. The lower metal layer BML may be a light blocking layer for protecting an active material layer ACT of the semiconductor layer from external light. The lower metal layer BML may include a material that blocks light. For example, the lower metal layer BML may be formed of an opaque metal material that blocks light transmission.

The lower metal layer BML may have a patterned shape. The lower metal layer BML may be disposed on a lower portion to cover at least a channel region of an active material layer ACT of a transistor TR of the display device 10, and may also cover an entire active material layer ACT of the transistor TR. However, embodiments are not limited thereto, and the lower metal layer BML may be omitted.

The buffer layer 12 may be disposed on the lower metal layer BML. The buffer layer 12 may cover an entire surface of the substrate 11 on which the lower metal layer BML is disposed. The buffer layer 12 may protect the transistor TR from moisture permeating through the substrate 11 that is vulnerable to moisture permeation. The buffer layer 12 may be formed as inorganic layers that are alternately stacked. For example, the buffer layer 12 may be formed as multiple layers in which inorganic layers including at least one of silicon oxide (SiOₓ), silicon nitride (SiNₓ), and silicon oxynitride (SiOₓN_{y}) are alternately stacked.

The semiconductor layer may be disposed on the buffer layer 12. The semiconductor layer may include the active material layer ACT of the transistor TR. The active material layer ACT may overlap the lower metal layer BML.

The semiconductor layer may include polycrystalline silicon, an oxide semiconductor, or the like. In an embodiment, in case that the semiconductor layer includes the polycrystalline silicon, the semiconductor layer may be formed by crystallizing amorphous silicon. In an embodiment, the semiconductor layer may also include an oxide semiconductor. Examples of the oxide semiconductor may include indium-tin oxide (ITO), indium-zinc oxide (IZO), indium-gallium oxide (IGO), indium-zinc-tin Oxide (IZTO), indium-gallium-zinc oxide (IGZO), indium-gallium-tin oxide (IGTO), and indium-gallium-zinc-tin oxide (IGZTO).

A gate insulating layer 13 may be disposed on the active material layer ACT. The gate insulating layer 13 may be disposed on the buffer layer 12 on which the active material layer ACT is disposed. The gate insulating layer 13 may function as a gate insulating layer of the transistor TR. The gate insulating layer 13 may be formed as an inorganic layer including an inorganic material such as silicon oxide (SiOₓ), silicon nitride (SiNₓ), or silicon oxynitride (SiOₓN_{y}), or may be formed in a stacked structure thereof.

A gate conductive layer 14 may be disposed on the gate insulating layer 13. The gate conductive layer 14 may include a gate electrode GE of the transistor TR and a first capacitive electrode CSE of a storage capacitor.

The gate electrode GE may overlap the channel region of the active material layer ACT in the thickness direction. The first capacitive electrode CSE may overlap a second source/drain electrode SD2 of the transistor TR to be described below in the thickness direction. The first capacitive electrode CSE may overlap the second source/drain electrode SD2 in the third direction DR3 to form a storage capacitor therebetween. In some embodiments, the first capacitive electrode CSE and the gate electrode GE may be integrated into a layer. A portion of the integrated layer may include the first gate electrode GE, and another portion of the integrated layer may include the first capacitive electrode CSE.

The gate conductive layer 14 may be formed as a single layer or multiple layers made of any one of molybdenum (Mo), aluminum (Al), chromium (Cr), gold (Au), titanium (Ti), nickel (Ni), neodymium (Nd), and copper (Cu), or an alloy thereof. However, embodiments are not limited thereto.

An interlayer insulating layer 15 may be disposed on the gate conductive layer 14. The interlayer insulating layer 15 may be disposed on the gate insulating layer 13 on which the gate conductive layer 14 is formed. The interlayer insulating layer 15 may include an inorganic insulating material such as silicon oxide (SiOₓ), silicon nitride (SiNₓ), or silicon oxynitride (SiOₓN_{y}).

A first data conductive layer 16 may be disposed on the interlayer insulating layer 15. The first data conductive layer 16 may include a first source/drain electrode SD1 and a second source/drain electrode SD2 of the transistor TR, and a data line DTL.

The first and second source/drain electrodes SD1 and SD2 may be connected (e.g., electrically connected) to end areas (e.g., opposite end areas) of the active material layer ACT (e.g., doping areas of the active material layer ACT) through contact holes penetrating through the interlayer insulating layer 15 and the gate insulating layer 13, respectively. For example, the second source/drain electrode SD2 of the transistor TR may be connected (e.g., electrically connected) to the lower metal layer BML through a contact hole penetrating through the interlayer insulating layer 15, the gate insulating layer 13, and the buffer layer 12.

The data line DTL may apply a data signal to another transistor included in the display device 10. For example, the data line DTL may be connected to a source/drain electrode of another transistor.

The first data conductive layer 16 may be formed as a single layer or multiple layers made of any one of molybdenum (Mo), aluminum (Al), chromium (Cr), gold (Au), titanium (Ti), nickel (Ni), neodymium (Nd), and copper (Cu), or an alloy thereof. However, embodiments are not limited thereto.

A passivation layer 17 may be disposed on the first data conductive layer 16. The passivation layer 17 may cover and protect the first data conductive layer 16. The passivation layer 17 may include an inorganic insulating material such as silicon oxide (SiOₓ), silicon nitride (SiNₓ), or silicon oxynitride (SiOₓN_{y}).

A second data conductive layer 18 may be disposed on the passivation layer 17. The second data conductive layer 18 may include a first voltage line VL1, a second voltage line VL2, and a first conductive pattern CDP.

A high-potential voltage (or a first power voltage) may be supplied to the first voltage line VL1, and a low-potential voltage (or a second power voltage) lower than the high-potential voltage (the first power voltage) of the first voltage line VL1 may be supplied to the second voltage line VL2. The second voltage line VL2 may be connected (e.g., electrically connected) to a second electrode 22 so as to supply the low-potential voltage (the second power voltage) to the second electrode 22. For example, an alignment signal necessary for aligning the light emitting element 30 may be applied to the second voltage line VL2 in a process of manufacturing the display device 10.

The first conductive pattern CDP may be connected (e.g., electrically connected) to the source/drain electrode SD2 of the transistor TR through a contact hole penetrating through the passivation layer 17. The first conductive pattern CDP may be connected (e.g., electrically connected) to a first electrode 21 through a first contact hole CT1 to be described below to transmit the first power voltage applied from the first voltage line VL1 to the first electrode 21.

The second data conductive layer 18 may be formed as a single layer or multiple layers made of any one of molybdenum (Mo), aluminum (Al), chromium (Cr), gold (Au), titanium (Ti), nickel (Ni), neodymium (Nd), and copper (Cu), or an alloy thereof. However, embodiments are not limited thereto.

The via layer 19 may be disposed on the second data conductive layer 18. The via layer 19 may be disposed on the passivation layer 17 on which the second data conductive layer 18 may be disposed. The via layer 19 may planarize the surface. The via layer 19 may include an organic insulating material, for example, an organic material such as polyimide (PI).

Hereinafter, a structure of the light emitting layer EML disposed on the via layer 19 will be described in detail with reference to FIG. 3 together with FIG. 2.

The wall 40 may be disposed on the via layer 19. The wall 40 may have a shape extending in the second direction DR2 within each sub-pixel SPX in a plan view. The wall 40 may be formed in a state of being spaced apart from a boundary area of the sub-pixel SPX adjacent in the second direction DR2 so as not to extend to the other sub-pixel SPX adjacent in the second direction DR2.

In an embodiment, the wall 40 included in each sub-pixel SPX may include a first wall 41 and a second wall 42. The first wall 41 and the second wall 42 may face each other and may be spaced apart from each other in the first direction DR1 in the light emitting area EMA. A space formed by the first wall 41 and the second wall 42 being spaced apart from each other may provide an area in which the light emitting elements 30 are disposed. In the drawings, each sub-pixel SPX is illustrated as including two walls (e.g., the first wall 41 and the second wall 42), but embodiments are not limited thereto. Each sub-pixel SPX may also include a larger number of walls 40 according to the shape or arrangement of the electrodes 21 and 22 to be described later.

The wall 40 (e.g., 41 and 42) may be disposed (e.g., directly disposed) on the via layer 19. The wall 40 may have a structure in which at least a portion thereof protrudes from an upper surface of the via layer 19. The protruding portion of the wall 40 may have an inclined side surface. The wall 40 may change a traveling direction of light emitted from the light emitting element 30 and traveling or transmitting toward the side surface of the wall 40 to an upper direction (e.g., a display direction) by including the inclined side surface. For example, the wall 40 may provide the space in which the light emitting element 30 is disposed as described above and also serve as a reflective wall that changes the traveling direction of the light emitted from the light emitting element 30 into the display direction. Although the drawing illustrates that the side surface of the wall 40 is inclined in a linear shape, embodiments are not limited thereto. For example, the side surface (or outer surface) of the wall 40 may have a curved semicircular or semielliptical shape. In an embodiment, the wall 40 may include an organic insulating material such as polyimide (PI), but embodiments are not limited thereto.

The electrodes 21 and 22 may be disposed on the wall 40 and the via layer 19 exposed by the wall 40. The electrodes 21 and 22 may include a first electrode 21 and a second electrode 22.

The first electrode 21 and the second electrode 22 may each have a shape extending in the second direction DR2 in a plan view. The first electrode 21 and the second electrode 22 may face each other and may be spaced apart from each other in the first direction DR1. A planar shape of the first electrode 21 and the second electrode 22 may be substantially similar to a planar shape of the first wall 41 and the second wall 42, respectively, but an area of the first electrode 21 and the second electrode 22 may be greater than an area of the first wall 41 and the second wall 42.

The first electrode 21 may extend in the second direction DR2 in a plan view to overlap a partial area of the bank 60 extending in the first direction DR1. The first electrode 21 may be in contact with the first conductive pattern CDP through the first contact hole CT1 penetrating through the via layer 19. The first electrode 21 may be connected (e.g., electrically connected) to the transistor TR through the first conductive pattern CDP.

The second electrode 22 may extend in the second direction DR2 in a plan view to overlap a partial area of the bank 60 extending in the first direction DR1. The second electrode 22 may be in contact with the second voltage line VL2 through a second contact hole CT2 penetrating through the via layer 19.

Although the drawing illustrates that the first contact hole CT1 and the second contact hole CT2 overlap the bank 60, embodiments are not limited thereto. For example, the first contact hole CT1 and the second contact hole CT2 may not overlap the bank 60, but may also be disposed in the light emitting area EMA surrounded by the bank 60.

The cut area CBA may be disposed between the light emitting areas EMA of the sub-pixel SPX adjacent to each other in the second direction DR2. The first electrode 21 and the second electrode 22 may be separated from other electrodes 21 and 22 included in the sub-pixel SPX adjacent to each other in the second direction DR2 in the cut area CBA within the sub-pixel SPX. Such a shape of the first electrode 21 and the second electrode 22 may be formed through a process of disconnecting each of the electrodes 21 and 22 in the cut area CBA after a process of disposing the light emitting element 30 during the process of manufacturing the display device 10. However, embodiments are not limited thereto, and some of the electrodes 21 and 22 may extend to the sub-pixel SPX adjacent in the second direction DR2 and may be integral with each other, or only one of the first electrode 21 and the second electrode 22 may be separated.

The shape and arrangement of the first electrode 21 and the second electrode 22 disposed in each sub-pixel SPX are not limited as long as at least some areas of the first electrode 21 and the second electrode 22 face each other and is spaced apart from each other to form a space in which the light emitting element 30 is disposed. Although FIGS. 2 and 3 illustrate that a single first electrode 21 and a single second electrode 22 are disposed in each of the sub-pixels SPX, embodiments are not limited thereto, and a larger number of first electrodes 21 and second electrodes 22 may be disposed in each of the sub-pixels SPX. For example, a planar shape of the first electrode 21 and the second electrode 22 disposed in each sub-pixel SPX is not limited to a shape extending in a direction, and may have a partially curved or bent shape, and the first electrode 21 and the second electrode 22 may be disposed such that an electrode may surround the other electrode.

The first electrode 21 may be disposed on the first wall 41 to cover the outer surface of the first wall 41. The first electrode 21 may extend outward from the side surface of the first wall 41 and may be disposed (e.g., partially disposed) on the upper surface of the via layer 19 exposed by the first wall 41 and the second wall 42.

The second electrode 22 may be disposed on the second wall 42 to cover the outer surface of the second wall 42. The second electrode 22 may extend outwardly from the side surface of the second wall 42 and may be disposed (e.g., partially disposed) on the upper surface of the via layer 19 exposed by the first wall 41 and the second wall 42. The first electrode 21 and the second electrode 22 may be spaced apart from each other in the first direction DR1 so as to expose at least a portion of the via layer 19 in an area between the first wall 41 and the second wall 42.

The first and second electrodes 21 and 22 may be connected (e.g., electrically connected) to the light emitting elements 30, respectively, and a voltage may be applied to the first and second electrodes 21 and 22 so that the light emitting element 30 emits light. For example, the electrodes 21 and 22 may be connected (e.g., electrically connected) to the light emitting element 30 disposed between the first electrode 21 and the second electrode 22 through contact electrodes 26 and 27 to be described below, and may transmit an electrical signal applied to the electrodes 21 and 22 to the light emitting element 30 through the contact electrodes 26 and 27.

In an embodiment, any one of the first electrode 21 and the second electrode 22 may be connected (e.g., electrically connected) to an anode electrode of the light emitting element 30. The other one of the first electrode 21 and the second electrode 22 may be connected (e.g., electrically connected) to a cathode electrode of the light emitting element 30. However, the first electrode 21 and the second electrode 22 are not limited thereto, and vice versa.

Each of the electrodes 21 and 22 may form an electric field in the sub-pixel SPX so as to align the light emitting elements 30. The light emitting element 30 may be disposed between the first electrode 21 and the second electrode 22 by an electric field formed on the first electrode 21 and the second electrode 22. In an embodiment, the light emitting elements 30 of the display device 10 may be sprayed onto the electrodes 21 and 22 by an inkjet printing process. In case that an ink including the light emitting elements 30 is sprayed onto the electrodes 21 and 22, an alignment signal may be applied to the electrodes 21 and 22 to generate an electric field. The light emitting elements 30 dispersed in the ink may be aligned on the electrodes 21 and 22 by a dielectrophoretic force caused by the electric field generated on the electrodes 21 and 22.

Each of the electrodes 21 and 22 may include a transparent conductive material. As an example, each of the electrodes 21 and 22 may include a material such as indium tin oxide (ITO), indium zinc oxide (IZO), or indium tin zinc oxide (ITZO), but embodiments are not limited thereto. In some embodiments, each of the electrodes 21 and 22 may include a conductive material having high reflectivity. For example, each of the electrodes 21 and 22 may include a metal such as silver (Ag), copper (Cu), or aluminum (Al) as the material having the high reflectivity. For example, each of the electrodes 21 and 22 may reflect the light emitted from the light emitting element 30 and traveling or transmitting to the side surface of each of the first and second walls 41 and 42 to travel in the display direction in each sub-pixel SPX. Embodiments are not limited thereto, and each of the electrodes 21 and 22 may have a structure in which one or more layers made of the transparent conductive material and one or more layers made of the metal having the high reflectivity are stacked or may be formed as a layer including the transparent conductive material and the metal having the high reflectivity. In an embodiment, each of the electrodes 21 and 22 may have a stacked structure of ITO/silver (Ag)/ITO, ITO/Ag/IZO, or ITO/Ag/ITZO/IZO, or be made of an alloy including aluminum (Al), nickel (Ni), lanthanum (La), or the like.

A first insulating layer 51 may be disposed on the electrodes 21 and 22. The first insulating layer 51 may be disposed on the via layer 19, the first electrode 21, and the second electrode 22, but may expose at least portions of the first electrode and the second electrode 22. The first insulating layer 51 may be formed on (e.g., entirely on) the via layer 19, including the area between the first electrode 21 and the second electrode 22, and may expose a portion of the first electrode 21 and the second electrode 22 overlapping the first wall 41 and the second wall 42.

The first insulating layer 51 may have a step formed so that a portion of an upper surface thereof may be recessed between the first electrode 21 and the second electrode 22. The first insulating layer 51 may be formed so that a portion of the upper surface thereof may be recessed due to a step formed by a member (e.g., the first electrode 21 and/or the second electrode 22) disposed on a lower side thereof. In some embodiments, an empty space may be formed between the light emitting element 30 and the upper surface of the first insulating layer 51 recessed (e.g., partially recessed) by the step formed between the first electrode 21 and the second electrode 22. The empty space between the first insulating layer 51 and the light emitting element 30 may be filled with a material of a second insulating layer 52 to be described below. However, embodiments are not limited thereto, and the first insulating layer 51 may not have the step formed between the first electrode 21 and the second electrode 22. For example, the first insulating layer 51 may also include a flat upper surface so that the light emitting element 30 may be disposed between the first electrode 21 and the second electrode 22.

The first insulating layer 51 may insulate the first electrode 21 and the second electrode 22 from each other and may protect the first electrode 21 and the second electrode 22. For example, the first insulating layer 51 may prevent the light emitting element 30 disposed on the first insulating layer 51 from being in direct contact with and being damaged by other members.

A bank 60 may be disposed on the first insulating layer 51. The bank 60 may be disposed in a lattice-shaped pattern on an entire surface of the display area DPA and may include portions extending in the first and second directions DR1 and DR2 in a plan view. The bank 60 may be disposed across a boundary area between the respective sub-pixels SPX to distinguish the sub-pixels SPX adjacent to each other. For example, according to an embodiment, the bank 60 may be formed to have a height greater than that of the wall 40. The bank 60 may perform a function of preventing ink from overflowing into an adjacent sub-pixel SPX in an inkjet printing process of the process of manufacturing the display device 10. The bank 60 may separate inks in which different light emitting elements 30 are dispersed in each of the different sub-pixels SPX from each other so as not to be mixed with each other.

The bank 60 may surround the light emitting area EMA and the cut area CBA disposed in each sub-pixel SPX to distinguish (or define) the light emitting area EMA and the cut area CBA. The first electrode 21 and the second electrode 22 may extend in the second direction DR2 and may cross a portion of the bank 60 extending in the first direction DR1. A portion disposed between the light emitting areas EMA of the portion of the bank 60 extending in the second direction DR2 may have a greater width than a portion thereof disposed between the cut areas CBA. Accordingly, a distance between the cut areas CBA may be smaller than a distance between the light emitting areas EMA. Each of the electrodes 21 and 22 may overlap the bank 60 disposed between the cut area CBA and the light emitting area EMA, and the contact holes CT1 and CT2 may be formed in the overlapped portions.

The bank 60 may include polyimide (PI) like the wall 40, but embodiments are not limited thereto.

The light emitting element 30 may be disposed on the first insulating layer 51 between the respective electrodes 21 and 22. The light emitting element 30 may have a shape extending in a direction. The light emitting elements 30 may be spaced apart from each other in the second direction DR2 in which the respective electrodes 21 and 22 extend, and may be aligned to be substantially parallel to each other. A distance between the light emitting elements 30 spaced apart from each other is not limited. For example, the light emitting element 30 may have a shape extending in a direction. The direction, in which each of the electrodes 21 and 22 extends, and the direction, in which the light emitting element 30 extends, may be substantially perpendicular to each other. However, embodiments are not limited thereto, and the light emitting element 30 may also be obliquely disposed so as not to perpendicular to the direction in which each of the electrodes 21 and 22 extends. A detailed description of a shape of the light emitting element 30 will be described below with reference to other drawings.

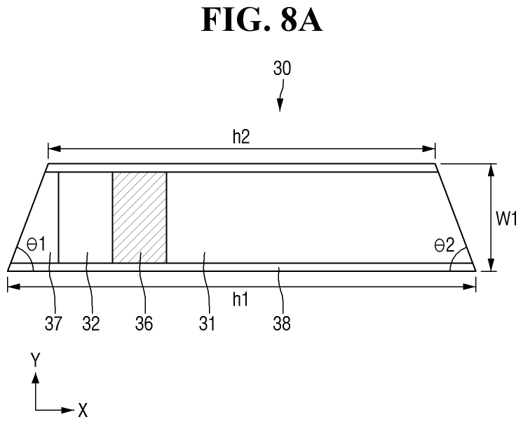

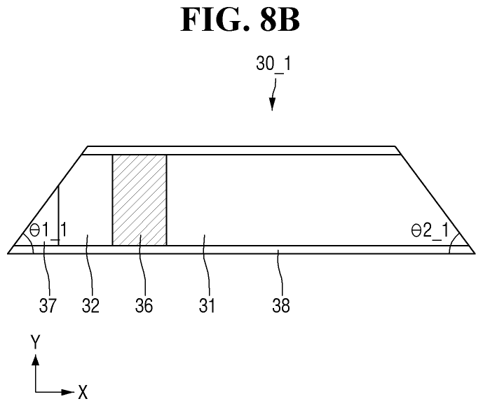

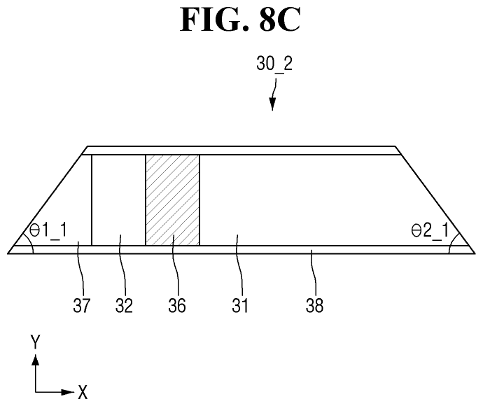

The light emitting element 30 may include an active layer 36 (see FIG. 8A) to emit light in a specific wavelength band to the outside. The display device 10 may include the light emitting elements 30 that emit light of different wavelength bands. Accordingly, light of a first color, a second color, and a third color may be emitted from the first sub-pixel SPX1, the second sub-pixel SPX2, and the third sub-pixel SPX3, respectively. However, embodiments are not limited thereto, and the light emitting element 30 included in each sub-pixel SPX may include the active layer 36 including the same material to emit light of substantially the same color.

The second insulating layer 52 may be disposed (e.g., partially disposed) on the light emitting element 30 disposed between the first electrode 21 and the second electrode 22. The second insulating layer 52 may surround (e.g., partially surround) an outer surface of the light emitting element 30. The second insulating layer 52 may be disposed on the light emitting element 30, but expose an end and another end portion of the light emitting element 30. A portion of the second insulating layer 52 disposed on the light emitting element 30 may have a shape extending in the second direction DR2 between the first electrode 21 and the second electrode 22 in a plan view. As an example, the second insulating layer 52 may form a linear pattern or an island-shaped pattern in each sub-pixel SPX. For example, as described above, the material of the second insulating layer 52 may be filled in the empty space between the first insulating layer 51 disposed between the first electrode 21 and the second electrode 22 and formed by being recessed and the light emitting element 30.

The second insulating layer 52 may protect the light emitting element 30 and may fix the light emitting element 30 in the process of manufacturing the display device 10.

Contact electrodes 26 and 27 may be disposed on the second insulating layer 52. The contact electrodes 26 and 27 may include a first contact electrode 26 and a second contact electrode 27.

The first and second contact electrodes 26 and 27 may have a shape extending in a direction in a plan view. Each of the first contact electrode 26 and the second contact electrode 27 may have a shape extending in the second direction DR2. The first contact electrode 26 and the second contact electrode 27 may be spaced apart from each other and may face each other in the first direction DR1. The first contact electrode 26 and the second contact electrode 27 may form a stripe-shaped pattern in the light emitting area EMA of each sub-pixel SPX.

The first and second contact electrodes 26 and 27 may be in contact with the light emitting element 30 and the electrodes 21 and 22, respectively. The first contact electrode 26 may be disposed on the first electrode 21, and the second contact electrode 27 may be disposed on the second electrode 22. The first contact electrode 26 and the second contact electrode 27 may cover (e.g., partially cover) upper surfaces of the first electrode 21 and the second electrode 22 and may be in contact with an end and another end portion of the light emitting element 30, respectively.

An end portion of the light emitting element 30 exposed by the second insulating layer 52 may be connected (e.g., electrically connected) to the first electrode 21 through the first contact electrode 26, and another end portion of the light emitting element 30 exposed by the second insulating layer 52 may be connected (e.g., electrically connected) to the second electrode 22 through the second contact electrode 27.

A third insulating layer 53 may be disposed on the first contact electrode 26. The third insulating layer 53 may electrically insulate the first contact electrode 26 and the second contact electrode 27 from each other. The third insulating layer 53 may cover the first contact electrode 26, but may not be disposed on another end portion of the light emitting element 30 so that the light emitting element 30 may be in contact with the second contact electrode 27.

The second contact electrode 27 may be disposed on the second electrode 22, the second insulating layer 52, and the third insulating layer 53. The second contact electrode 27 may be in contact with another end portion of the light emitting element 30 and an exposed upper surface of the second electrode 22. Another end portion of the light emitting element 30 may be connected (e.g., electrically connected) to the second electrode 22 through the second contact electrode 27.

The first and second contact electrodes 26 and 27 may include a conductive material. For example, the contact electrodes 26 and 27 may include ITO, IZO, ITZO, aluminum (Al), or the like. As an example, the contact electrodes 26 and 27 may include a transparent conductive material, but embodiments are not limited thereto.

A fourth insulating layer 54 may be disposed (e.g., entirely disposed) on the substrate 11. The fourth insulating layer 54 may protect the members disposed on the substrate 11 from an external environment.

Each of the first insulating layer 51, the second insulating layer 52, the third insulating layer 53, and the fourth insulating layer 54 described above may include an inorganic insulating material or an organic insulating material. In an embodiment, the first insulating layer 51, the second insulating layer 52, the third insulating layer 53, and the fourth insulating layer 54 may include an inorganic insulating material such as silicon oxide (SiOₓ), silicon nitride (SiNₓ), silicon oxynitride (SiOₓN_{y}), aluminum oxide (Al₂O₃), or aluminum nitride (AlN). In another example, the first insulating layer 51, the second insulating layer 52, the third insulating layer 53, and the fourth insulating layer 54 may include an organic insulating material such as an acrylic resin, an epoxy resin, a phenolic resin, a polyamide resin, a polyimide resin, an unsaturated polyester resin, a polyphenylene resin, a polyphenylene sulfide resin, benzocyclobutene, a cardo resin, a siloxane resin, a silsesquioxane resin, polymethylmethacrylate, polycarbonate, or a polymethylmethacrylate-polycarbonate synthetic resin. However, embodiments are not limited thereto.

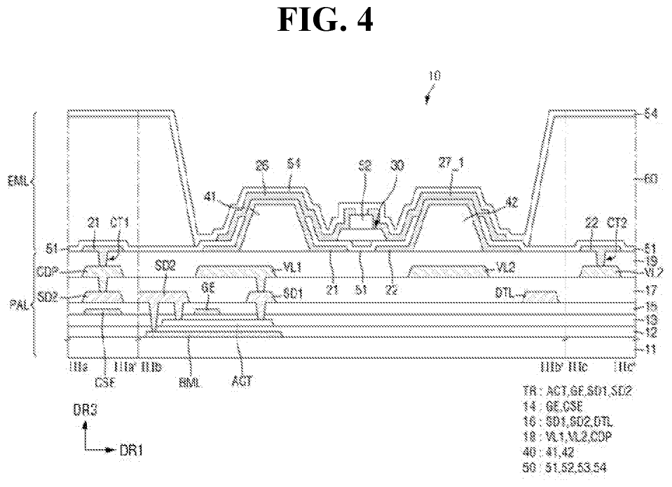

FIG. 4 is a partial schematics cross-sectional view of the display device 10 according to an embodiment.

Referring to FIG. 4, the third insulating layer 53 may be omitted in the display device 10. A portion of a second contact electrode 27_1 may be disposed (e.g., directly disposed) on the second insulating layer 52. The first contact electrode 26 and the second contact electrode 27_1 may be spaced apart from each other on the second insulating layer 52. In an embodiment, in case that the third insulating layer 53 is omitted, the second insulating layer 52 may perform a function of fixing the light emitting element 30 by including an organic insulating material. For example, the first contact electrode 26 and the second contact electrode 27_1 may be simultaneously formed by a patterning process. The embodiment of FIG. 4 is the same as the embodiment of FIG. 3 except that the third insulating layer 53 is further omitted. Hereinafter, a redundant will be omitted for descriptive convenience.

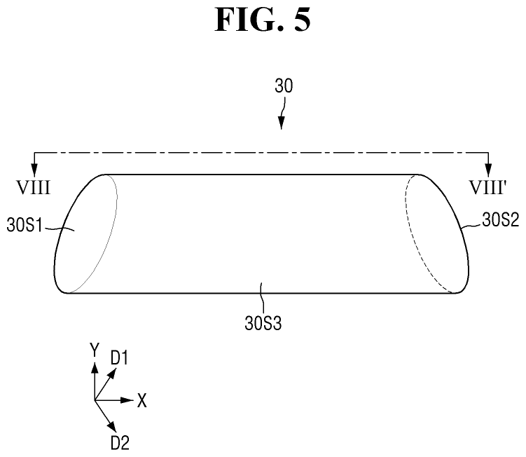

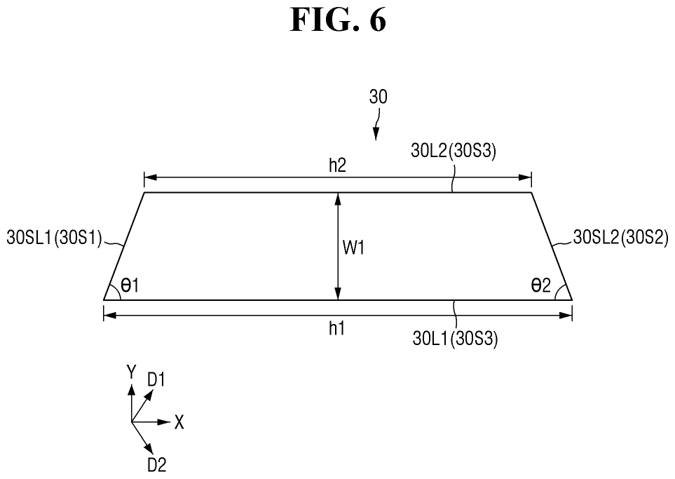

FIG. 5 is a schematic perspective view of a light emitting element 30 according to an embodiment. FIG. 6 is a schematic side view of the light emitting element 30 of FIG. 5.

The light emitting element 30 may be a light emitting diode. For example, the light emitting element 30 may have a size of a micro-meter or a nano-meter unit, and may be an inorganic light emitting diode made of an inorganic material. The inorganic light emitting diode may be aligned between two electrodes in which polarities are formed in case that an electric field is formed in a specific direction between the two electrodes facing each other. The light emitting element 30 may be aligned between the two electrodes by the electric field formed on the two electrodes.

Referring to FIG. 5, the light emitting element 30 according to an embodiment may have a shape extending in an X-axis direction. For example, the light emitting element 30 may have a pillar shape or a rod shape. However, the shape of the light emitting element 30 is not limited thereto, and the light emitting element 30 may have a polygonal prism shape, such as a rectangular parallelepiped or hexagonal prism extending in the X-axis direction.

The light emitting element 30 may include a semiconductor layer doped with an arbitrary conductivity-type impurity (e.g., a p-type dopant or an n-type dopant). The semiconductor layer may receive an electrical signal applied from an external power source to emit light in a specific wavelength band.

The light emitting element 30 may extend in the X-axis direction and include a first end portion 30S1 and a second end portion 30S2 inclined with respect to the X-axis direction. The light emitting element 30 may include a first surface 30S1, a second surface 30S2, and a third surface 30S3. Hereinafter, for convenience of explanation, the terms of the first surface 30S1 and the first end portion 30S1, and the second surface 30S2 and the second end portion 30S2 may be used interchangeably.

The first surface 30S1 may be the first end portion 30S1 of the light emitting element 30, the second surface 30S2 may be the second end portion 30S2 of the light emitting element 30, and the third surface 30S3 may be a side surface of the light emitting element 30 connecting the first surface 30S1 and the second surface 30S2 to each other or an outer surface of the light emitting element 30 extending in the X-axis direction.

The first end portion 30S1 and the second end portion 30S2 may be inclined with respect to the X-axis direction, which is the extension direction of the light emitting element 30. An inclined extension surface of the first end portion 30S1 may be inclined with respect to the X-axis direction, which is the extension direction of the light emitting element 30. For example, an inclined extension surface of the second end portion 30S2 may be inclined with respect to the X-axis direction, which is the extension direction of the light emitting element 30.

With respect to a Y-axis direction that vertically intersects a central portion of the light emitting element 30 in the X-axis direction, an inclined surface of the first end portion 30S1 may be inclined toward a side (e.g., upper portion in the drawing) in the Y-axis direction. For example, an inclined surface of the second end portion 30S2 may be inclined toward a side (e.g., upper portion in the drawing) in the Y-axis direction. For example, with respect to the Y-axis direction that vertically intersects the central portion of the light emitting element 30 in the X-axis direction, the first end portion 30S1 and the second end portion 30S2 of the light emitting element 30 may be inclined toward a side in the Y-axis direction, respectively. Accordingly, the inclined surface of the first end portion 30S1 and the inclined surface of the second end portion 30S2 of the light emitting element 30 may be inclined in a direction in which the inclined surface of the first end portion 30S1 and the inclined surface of the second end portion 30S2 of the light emitting element 30 are closer to each other as moving in the Y-axis direction and are farther from each other as moving in the opposite direction to the Y-axis direction. The third surface 30S3 may extend in parallel to the X-axis direction, which is the extension direction of the light emitting element 30.

Embodiments are not limited thereto. For example, a planar shape of the first end portion 30S1 may be an ellipse. For example, a planar shape of the second end portion 30S2 may be an ellipse. However, the surface shape of the first end portion 30S1 and the second end portion 30S2 is not limited thereto, and may be a rounded rectangle or other polygonal shapes.

FIG. 6 is a schematic cross-sectional view of the light emitting element 30 taken along the X-axis direction, which is the extension direction of the light emitting element 30. Referring to FIGS. 5 and 6, the cross section of the light emitting element 30 taken along the X-axis direction may include a first side 30L1, a second side 30L2, a first lateral side 30SL1, and a second lateral side 30SL2.

The first side 30L1 may be a side extending in the X-axis direction. The second side 30L2 may be a side that extends in the X-axis direction and opposes to the first side 30L1. The first side 30L1 and the second side 30L2 may be substantially parallel, and a width W1 between the first side 30L1 and the second side 30L2 may be substantially constant.

The first lateral side 30SL1 may be a side connecting an end portion of the first side 30L1 and an end portion of the second side 30L2 to each other. The second lateral side 30SL2 may be a side connecting another end portion of the first side 30L1 and another end portion of the second side 30L2 to each other.

The second side 30L2 may overlap the first side 30L1 in a Y-axis direction perpendicular to the the X-axis direction. For example, lengths of the first side 30L1 and the second side 30L2 in the X-axis direction may be different from each other. In an embodiment, a length h1 of the first side 30L1 in the X-axis direction may be longer than a length h2 of the second side 30L2 in the X-axis direction. As the second side 30L2 overlaps the first side 30L1 in the Y-axis direction, but the length h2 of the second side 30L2 is smaller than the length h1 of the first side 30L1, the first lateral side 30SL1 and the second lateral side 30SL2 may be inclined at an acute angle from the first side 30L1. For example, the first lateral side 30SL1 may be inclined in a first diagonal direction D1, which rises from left to right (or falls from right to left), and the second lateral side 30SL2 may be inclined in a second diagonal direction D2, which falls from left to right (or rises from right to left). For example, the first diagonal direction D1 may be between the X-axis direction and the Y-axis direction, and the second diagonal direction D2 may be between the X-axis direction and an opposite direction to the Y-axis direction.

For example, the first side 30L1 and the first lateral side 30SL1 may be inclined to each other at a first interior angle θ1. The first interior angle θ1 formed between the first side 30L1 and the first lateral side 30SL1 may be an acute angle. For example, a size of the first interior angle θ1 may be 75° or less. However, embodiments are not limited thereto.

The first side 30L1 and the second lateral side 30SL2 may be inclined to each other at a second interior angle θ2. The second interior angle θ2 formed between the first side 30L1 and the second lateral side 30SL2 may be an acute angle. For example, a size of the second interior angle θ2 may be 75° or less. However, embodiments are not limited thereto.

In an embodiment, the size of the first interior angle θ1 and the size of the second interior angle θ2 may be the same as each other. For example, the light emitting element 30 may include a shape that is symmetrical with respect to a cut surface that vertically crosses the central portion of the light emitting element 30 in the X-axis direction. However, embodiments are not limited thereto, and the size of the first interior angle θ1 and the size of the second interior angle θ2 may be different from each other.

As described above, in case that the sizes of the first interior angle θ1 and the second interior angle θ2 are the acute angle, it is possible to prevent a residual film of the second insulating layer 52 from remaining in areas adjacent to the first end portion 30S1 and the second end portion 30S2 of the light emitting element 30 in a process of etching the second insulating layer 52 of the display device 10 to be described below.

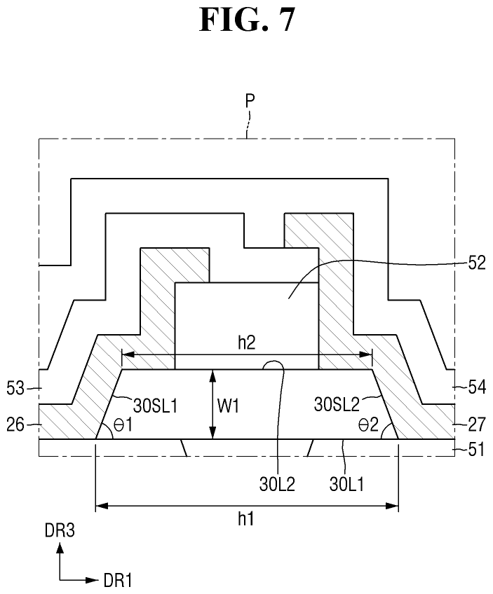

FIG. 7 is a schematic enlarged cross-sectional view of area P of FIG. 3.

Referring to FIG. 7 together with FIGS. 3 and 5, the light emitting element 30 may be disposed on the first insulating layer 51 disposed between the first electrode 21 and the second electrode 22. The X-axis direction, which is the extension direction of the light emitting element 30 described above, may be substantially parallel to the upper surface of the substrate 11. For example, the extension direction of the light emitting element 30 may be substantially parallel to the upper surface of the substrate 11.

The first side 30L1 of the light emitting element 30 may face the first insulating layer 51. The second side 30L2 of the light emitting element 30 may face an opposite side of the side facing the first insulating layer 51, e.g., an upper portion. For example, the light emitting element 30 may be disposed on the first insulating layer 51 so that the first side 30L1, which is a long side, may be disposed at a lower portion, and the second side 30L2, which is a short side, may face the upper portion.

As described above, in the arrangement in which the first side 30L1, which is the long side of the light emitting element 30 in the cross-sectional view, is disposed at the lower portion and the second side 30L2, which is the short side, is disposed at the upper portion, as a dielectrophoretic force applied to the first side 30L1 having a relatively large area is strong in a process of aligning the light emitting element 30 using the dielectrophoretic force, the light emitting element 30 may be aligned so that the first side 30L1 of the light emitting element 30 is positioned at the lower portion.

The first end portion 30S1 of the light emitting element 30 may overlap an upper surface of the first insulating layer 51 disposed on the first electrode 21 in the third direction DR3, and the second end portion 30S2 of the light emitting element 30 may overlap the first insulating layer 51 disposed on the second electrode 22 in the third direction DR3. For example, the first end portion 30S1 of the light emitting element 30 may overlap the first electrode 21 in the third direction DR3, and the second end portion 30S2 thereof may overlap the second electrode 22 in the third direction DR3. The first side 30L1 of the light emitting element 30 may be at least partially in contact with the upper surface of the first insulating layer 51.

Hereinafter, in case that a surface or line extends in a side in the third direction DR3 in a case where a direction in which the surface or line extends based on the upper surface of the substrate 11 parallel to the first direction DR1 increases in the first direction DR1, it is defined herein as “a slope of the surface or line is in a positive direction”. For example, in case that the surface or line extends to the “upper right or lower left” in the drawings, the slope of the surface or line may be defined as the positive direction. In case that a surface or line extends in another side in the third direction DR3 in a case where a direction in which the surface or line extends based on the upper surface of the substrate 11 parallel to the first direction DR1 increases in the first direction DR1, it is defined herein as “a slope of the surface or line is in a negative direction”. For example, in case that the surface or line extends to the “lower right or upper left” in the drawings, the slope of the surface or line may be defined as the negative direction.

The inclined surface of the first end portion 30S1 of the light emitting element 30 may be inclined in the positive direction with respect to the upper surface of the substrate 11. The inclined surface of the second end portion 30S2 of the light emitting element 30 may be inclined in the negative direction with respect to the upper surface of the substrate 11. However, embodiments are not limited thereto, and the inclined surface of the first end portion 30S1 of the light emitting element 30 may also be inclined in the negative direction with respect to the upper surface of the substrate 11. For example, the inclined surface of the second end portion 30S2 of the light emitting element 30 may also be inclined in the positive direction with respect to the upper surface of the substrate 11. For example, the inclined surface of the first end portion 30S1 and the inclined surface of the second end portion 30S2 of the light emitting element 30 may be inclined in the positive direction or the negative direction with respect to the upper surface of the substrate 11, respectively. For example, the directions in which the inclined surface of the first end portion 30S1 and the inclined surface of the second end portion 30S2 may be inclined with respect to the upper surface of the substrate 11 may be opposite to each other.

The first lateral side 30SL1 of the light emitting element 30 may have an inclination of an acute angle with the upper surface of the first insulating layer 51. For example, the second lateral side 30SL2 of the light emitting element 30 may have an inclination of an acute angle with the upper surface of the first insulating layer 51.

The second insulating layer 52 may be disposed on the light emitting element 30. The second insulating layer 52 may be disposed on the second side 30L2 of the light emitting element 30. The second insulating layer 52 may be in contact with the second side 30L2 of the light emitting element 30.

The second insulating layer 52 may be disposed on the light emitting element 30 to expose the first end portion 30S1 and the second end portion 30S2 of the light emitting element 30 in the third direction DR3. The second insulating layer 52 may not overlap the first end portion 30S1 and the second end portion 30S2 of the light emitting element 30 in the third direction DR3. The second insulating layer 52 may expose the first lateral side 30SL1 of the light emitting element 30 and the second lateral side 30SL2 of the light emitting element 30. For example, the second insulating layer 52 may not overlap the first lateral side 30SL1 and the second lateral side 30SL2.

The first contact electrode 26 may be disposed on the first insulating layer 51. The first contact electrode 26 may be in contact with the first electrode 21 and the first end portion 30S1 of the light emitting element 30. For example, the first contact electrode 26 may be in contact with the first electrode 21 and the first lateral side 30SL1 of the light emitting element 30. The first contact electrode 26 may be in contact with each of the first electrode 21 and the first lateral side 30SL1 of the light emitting element 30 to connect (e.g., electrically connect) the first electrode 21 and the light emitting element 30 to each other.

The second contact electrode 27 may be disposed on the first insulating layer 51. The second contact electrode 27 may be in contact with the second electrode 22 and the second end portion 30S2 of the light emitting element 30. For example, the second contact electrode 27 may be in contact with the first electrode 21 and the second lateral side 30SL2 of the light emitting element 30. The second contact electrode 27 may be in contact with each of the first electrode 22 and the second lateral side 30SL2 of the light emitting element 30 to connect (e.g., electrically connect) the second electrode 22 and the light emitting element 30 to each other.

In the embodiment, as the first end portion 30S1 and the second end portion 30S2 of the light emitting element 30 extending in a direction are formed to have an angle from the upper surface of the first insulating layer 51 on which the light emitting element 30 is disposed, the light emitting element 30 may have the first lateral side 30SL1 and the second lateral side 30SL2 inclined at an acute angle from the first side 30L1 in a cross-sectional view. As the first lateral side 30SL1 and the second lateral side 30SL2 are formed to be inclined from the first side 30L1, a length of the first lateral side 30SL1 and the second lateral side 30SL2 may be greater than a width W1 between the first side 30L1 and the second side 30L2. Accordingly, areas (or sizes) of the first end portion 30S1 and the second end portion 30S2, which are formed to be inclined from the third surface 30S3, may be greater than areas (or sizes) of the first end portion 30S1 and the second end portion 30S2, which are formed to be perpendicular to the third surface 30S3. For example, in the light emitting element 30 having the same width W1, in case that the first end portion 30S1 and the second end portion 30S2 are inclined with respect to the first side 30L1, a contact area of the first end portion 30S1 and the second end portion 30S2 in contact with the first contact electrode 26 and the second contact electrode 27 may increase, and thus contact reliability may be improved.

For example, as the first lateral side 30SL1 and the second lateral side 30SL2 are formed to be inclined from the first side 30L1, it is possible to prevent a residual film of the material layer of the second insulating layer 52 from being generated in the areas adjacent to end portions (e.g., opposite end portions) of the light emitting element 30 in the process of patterning the second insulating layer 52 disposed on the light emitting element 30. For example, in order to form a patterned second insulating layer 52, a second insulating material layer may be entirely applied onto the first insulating layer 51, and the second insulating layer 52 may be patterned by an etching process. In the etching process, as end portions (e.g., opposite end portions) 30S1 and 30S2 of the light emitting element 30 are formed to be inclined, and the light emitting element 30 is arranged on the first insulating layer 51 to be inclined in an inner direction of the light emitting element 30, the etchant may be uniformly sprayed on the second insulating material layer disposed adjacent to end portions (e.g., opposite end portions) 30S1 and 30S2 of the light emitting element 30 to prevent the residual film of the second insulating material layer from remaining in end portions (e.g., opposite end portions) 30S1 and 30S2 of the light emitting element 30. Accordingly, contact reliability between the contact electrodes 26 and 27 in contact with end portions (e.g., opposite end portions) 30S1 and 30S2 of the light emitting element 30 and the light emitting element 30 may be improved.

FIG. 8A is a schematic cross-sectional view of the light emitting element according to an embodiment, and is a schematic cross-sectional view taken along line VIII-VIII′ of FIG. 5.

Referring to FIG. 8A, the light emitting element 30 may include a semiconductor core and an insulating layer 38 surrounding the semiconductor core. The semiconductor core of the light emitting element 30 may include a first semiconductor layer 31, a second semiconductor layer 32, an active layer 36, and an electrode layer 37. In an embodiment, the light emitting element 30 may have a shape extending in the X-axis direction, and may have a structure in which each layer of the semiconductor core is stacked in the X-axis direction, which is the extension direction of the light emitting element 30. Each interface (or boundary surface) between the first semiconductor layer 31, the active layer 36, the second semiconductor layer 32, and the electrode layer 37 may be substantially parallel to the Y-axis direction that vertically intersects the the X-axis direction, but embodiments are not limited thereto. In the descriptions, “the interface (or boundary surface) between the layers constituting the semiconductor core is parallel to the Y-axis direction” may include not only a complete form in which the interface (or boundary surface) between the layers is a plane, but also a form in which the interface (or boundary surface) between the layers is viewable as a substantially plane. For example, this may include a case in which curves or irregularities are generally on a plane in case that there are curves or irregularities in some sections of the interface (or boundary surface) between the layers. For example, this may include a case in which the interface (or boundary surface) between the layers is viewed to be substantially parallel to the Y-axis direction when viewed with the naked eye in case that the interface (or boundary surface) between the layers is not completely parallel to the Y-axis direction perpendicular to the X-axis direction that is the extension direction of the light emitting element 30.

The first semiconductor layer 31 may be an n-type semiconductor. As an example, in case that the light emitting element 30 emits light of a blue wavelength band, the first semiconductor layer 31 may include a semiconductor material having a chemical formula of AlₓGa_{y}In_{1-x-y}N (0≤x≤1, 0≤y≤1, and 0≤x+y≤1). For example, the semiconductor material may be any one or more of AlGaInN, GaN, AlGaN, InGaN, AlN, and InN doped with an n-type dopant. The first semiconductor layer 31 may be doped with an n-type dopant, which may be, for example, Si, Ge, Sn, or the like. In an embodiment, the first semiconductor layer 31 may be n-GaN doped with Si as an n-type dopant.

The second semiconductor layer 32 may be spaced apart from the first semiconductor layer 31 in the extension direction (e.g., X-axis direction) of the light emitting element 30. The second semiconductor layer 32 may be a p-type semiconductor, and as an example, in case that the light emitting element 30 emits light of a blue or green wavelength band, the second semiconductor layer 32 may include a semiconductor material having a chemical formula of AlₓGa_{y}In_{1-x-y}N (0≤x≤1, 0≤y≤1, and 0≤x+y≤1). For example, the semiconductor material may be any one or more of AlGaInN, GaN, AlGaN, InGaN, AlN, and InN doped with a p-type dopant. The second semiconductor layer 32 may be doped with a p-type dopant, which may be, for example, Mg, Zn, Ca, Se, Ba, or the like. In an embodiment, the second semiconductor layer 32 may be p-GaN doped with Mg as a p-type dopant.

It is illustrated in the drawings that the first semiconductor layer 31 and the second semiconductor layer 32 are configured as a single layer, but embodiments are not limited thereto. According to some embodiments, the first semiconductor layer 31 and the second semiconductor layer 32 may further include a larger number of layers, for example, a clad layer or a tensile strain barrier reducing (TSBR) layer, according to a material of an active layer 36 to be described below.

The active layer 36 may be disposed between the first semiconductor layer 31 and the second semiconductor layer 32. The active layer 36 may include a material having a single quantum well structure or a multiple quantum well structure. In case that the active layer 36 includes the material having the multiple quantum well structure, the active layer 36 may have a structure in which quantum layers and well layers are alternately stacked. The active layer 36 may emit light by a combination of electron-hole pairs according to electrical signals applied through the first semiconductor layer 31 and the second semiconductor layer 32. In case that the active layer 36 emits light of a blue wavelength band, the active layer 36 may include a material such as AlGaN or AlGaInN. In case that the active layer 36 has a structure in which the quantum layers and the well layers are alternately stacked as the multiple quantum well structure, the quantum layers may include a material such as AlGaN or AlGaInN, and the well layers may include a material such as GaN or AlInN. In an embodiment, the active layer 36 may include AlGaInN as the quantum layers and AlInN as the well layers to emit blue light having a central wavelength band of about 450 nm to about 495 nm as described above.

However, embodiments are not limited thereto, and the active layer 36 may have a structure in which a type of semiconductor material having a large band gap energy and a semiconductor material having a small band gap energy are alternately stacked with each other, and may include other Group III to Group V semiconductor materials according to a wavelength band of emitted light. The light emitted by the active layer 36 is not limited to the light of the blue wavelength band, and in some cases, the active layer 36 may emit light of a red and green wavelength band.

For example, the light emitted from the active layer 36 may be emitted not only to end surfaces (e.g., opposite end surfaces) of the light emitting element 30 in the extension direction (e.g., X-axis direction), but also to both side surfaces thereof. For example, the light generated from the active layer 36 of the light emitting element 30 may be emitted through the first surface 30S1, the second surface 30S2, and the third surface 30S3 of the light emitting element 30. For example, a direction of the light emitted from the light emitting element 30 is not limited to a direction.

The electrode layer 37 may be disposed on another side opposite to a side on which the active layer 36 is disposed from the second semiconductor layer 32 along the extension direction (e.g., X-axis direction) of the light emitting element 30. For example, the semiconductor core may have a structure in which the electrode layer 37, the second semiconductor layer 32, the active layer 36, and the first semiconductor layer 31 are sequentially stacked along the X-axis direction, which is the extension direction of the light emitting element 30.

The electrode layer 37 may be an ohmic contact electrode. However, embodiments are not limited thereto, and the electrode layer 37 may also be a Schottky contact electrode. The light emitting element 30 may include at least one electrode layer 37. Although FIG. 8A illustrates that the light emitting element 30 includes an electrode layer 37, embodiments are not limited thereto. In some cases, the light emitting element 30 may include a larger number of electrode layers 37 or the electrode layer 37 may be omitted. The description of the light emitting element 30 to be described below may be applied in case that the number of electrode layers 37 is changed or the light emitting element 30 further includes another structure.

The electrode layer 37 may decrease resistance between the light emitting element 30 and the electrodes 21 and 22 or the contact electrodes 26 and 27 in case that the light emitting element 30 is connected (e.g., electrically connected) to the electrodes 21 and 22 or the contact electrodes 26 and 27 in the display device 10 according to an embodiment. The electrode layer 37 may include a conductive metal. For example, the electrode layer 37 may include at least one of aluminum (Al), titanium (Ti), indium (In), gold (Au), silver (Ag), indium tin oxide (ITO), indium zinc oxide (IZO), and indium tin zinc oxide (ITZO). For example, the electrode layer 37 may include a semiconductor material doped with an n-type dopant or a p-type dopant. The electrode layer 37 may include the same material or different materials, but embodiments are not limited thereto.

The insulating layer 38 may surround an outer surface of the semiconductor core. In an embodiment, the insulating layer 38 may surround at least an outer surface of the active layer 36, and may extend in the X-axis direction in which the light emitting element 30 extends. The insulating layer 38 may perform a function of protecting the members. As an example, the insulating layer 38 may be formed to surround side surface portions of the members, but may be formed to expose end portions (e.g., opposite end portions) of the light emitting element 30 in the extension direction (e.g., X-axis direction).

Although it is illustrated in the drawings that the insulating layer 38 is formed to extend in the extension direction (e.g., X-axis direction) of the light emitting element 30 to cover from the first semiconductor layer 31 to the side surface of the electrode layer 37, embodiments are not limited thereto. The insulating layer 38 may cover only outer surfaces of some semiconductor layers, including the active layer 36, or cover only a portion of the electrode layer 37 to expose (e.g., partially expose) the outer surface of each electrode layer 37. For example, the insulating layer 38 may also be formed so that an upper surface thereof may be rounded in cross section in an area adjacent to at least one end portion of the light emitting element 30.

A thickness of the insulating layer 38 may be in the range of about 10 nm to about 1.0 but embodiments are not limited thereto. For example, the thickness of the insulating layer 38 may be about 40 nm.

In some embodiments, the insulating layer 38 may be disposed along the outer surface of the semiconductor core, but the thickness of the insulating layer 38 may not be uniform. The insulating layer 38 may have different thicknesses on the outer surfaces of the first semiconductor layer 31, the active layer 36, the second semiconductor layer 32, and the electrode layer 37. This may be because the insulating layer 38 has different thicknesses according to positions as the insulating layer 38 is etched during the process of manufacturing the light emitting element 30 or the insulating layer 38 is etched (e.g., partially etched) after the light emitting element 30 is disposed on the display device 10.

The insulating layer 38 may include materials having insulating properties, for example, silicon oxide (SiOₓ), silicon nitride (SiNₓ), silicon oxynitride (SiOₓN_{y}), aluminum nitride (AlN), and aluminum oxide (Al₂O₃). Accordingly, an electrical short circuit occurred in case that the active layer 36 is in direct contact with an electrode through which an electrical signal is transmitted to the light emitting element 30 may be prevented. For example, as the insulating layer 38 protects the outer surface of the semiconductor core, including the active layer 36, a decrease (or degradation) in light emission efficiency may be prevented.

For example, in some embodiments, an outer surface of the insulating layer 38 may be surface-treated. The light emitting elements 30 may be aligned by being sprayed onto the electrodes 21 and 22 in a state of being dispersed in an ink. Here, in order for the light emitting elements 30 to maintain the dispersed state without being aggregated with other adjacent light emitting elements 30 in the ink, a hydrophobic or hydrophilic treatment may be performed on a surface of the insulating layer 38.

Referring to FIGS. 5 and 8, the electrode layer 37 may be positioned in an end area in which the first end portion 3051 of the light emitting element 30 is positioned, and the first semiconductor layer 31 may be positioned in the other end area in which the second end portion 30S2 of the light emitting element 30 is positioned. The first end portion 30S1 of the light emitting element 30 may include an outer surface of the electrode layer 37, and the second end portion 30S2 may include an outer surface of the first semiconductor layer 31. The outer surface of the electrode layer 37 and the outer surface of the first semiconductor layer 31 may be surfaces exposed to the outside without being covered by the insulating layer 38. In the embodiment in which the first end portion 3051 and the second end portion 30S2 of the light emitting element 30 are inclined with respect to the X-axis direction, which is the extension direction of the light emitting element 30, the outer surfaces of the electrode layer 37 and the first semiconductor layer 31 may be inclined with respect to the X-axis direction, respectively.

As described above, the acute angles (e.g., the first interior angle θ1 or the second interior angle θ2), at which the first end portion 30S1 and the second end portion 30S2 are inclined with respect to the X-axis direction that is the extension direction of the light emitting element 30, may be respectively 75° or less.

FIG. 8B is a schematic cross-sectional view illustrating another example of a light emitting element taken along the line VIII-VIII′ of FIG. 5.

Referring to FIGS. 5 and 8B, a light emitting element 30_1 of FIG. 8B is different from the light emitting element 30 of FIG. 8A in that a second semiconductor layer 32 may be further positioned in an end area in which a first end portion 30S1 of the light emitting element 30_1 is positioned. For example, the second semiconductor layer 32 of the light emitting element 30_1 may also form the first end portion 30S1 of the light emitting element 30_1 and may include an inclined surface.

For example, the electrode layer 37 and the second semiconductor layer 32 may be positioned in an end area in which the first end portion 30S1 of the light emitting element 30_1 is positioned. The first end portion 30S1 of the light emitting element 30_1 may include outer surfaces of the electrode layer 37 and the second semiconductor layer 32. The outer surface of the electrode layer 37 of the light emitting element 30_1 and a partial area of the second semiconductor layer 32, e.g., the outer surface of the second semiconductor layer 32, may be inclined with respect to the X-axis direction. The outer surface of the electrode layer 37 and the outer surface of the second semiconductor layer 32 may be surfaces exposed to the outside of the light emitting element 30_1 without being covered by the insulating layer 38.

As an example, in case that the inclination angles (e.g., the first interior angle θ1 or the second interior angle θ2) of end portions (e.g., opposite end portions) 30S1 and 30S2 of the light emitting element 30_1 are formed to be smaller in order to prevent the second insulating material layer from remaining on end portions (e.g., opposite end portions) 30S1 and 30S2 of the light emitting element 30_1 in the process of patterning the second insulating layer 52 disposed on the light emitting element 30_1 as described above with reference to FIG. 7, the light emitting element 30_1 in which the first end portion 30S1 includes the outer surfaces of the electrode layer 37 and the second semiconductor layer 32 may be formed.

As another example, in case that the inclination angles (e.g., the first interior angle θ1 or the second interior angle θ2) of the end portions (e.g., opposite end portions) 30S1 and 30S2 of the light emitting element 30_1 are similar to those of FIG. 8A, but the thickness of the electrode layer 37 in the X-axis direction is thin, a partial area of the second semiconductor layer 32 positioned at an end area in which the first end portion 30S1 is positioned may be also cut in a process of cutting end portions (e.g., opposite end portions) 30S1 and 30S2 of the light emitting element 30 to be inclined. Thus, the light emitting element 30_1, in which the first end portion 30S1 includes the outer surfaces of the electrode layer 37 and the second semiconductor layer 32, may be formed as in the embodiment. A detailed description of the process of cutting end portions (e.g., opposite end portions) 30S1 and 30S2 of the light emitting element 30_1 to be inclined will be described below with reference to other drawings illustrating a method of manufacturing the light emitting element.

For example, in case that the light emitting element 30_1 of FIG. 8B is disposed between the first electrode 21 and the second electrode 22 on the substrate 11, the electrode layer 37 and the second semiconductor layer 32 may form the first end portion 30S1 of the light emitting element 30_1, and the first semiconductor layer 31 may form the second end portion 30S2 thereof. Accordingly, the first contact electrode 26 may be in contact with the first electrode 21, the electrode layer 37, and the second semiconductor layer 32, and the second contact electrode 27 may be in contact with the second electrode 22 and the first semiconductor layer 31.

FIG. 8C is a schematic cross-sectional view illustrating another example of a light emitting element taken along the line VIII-VIII′ of FIG. 5.

Referring to FIGS. 5 and 8C, a light emitting element 30_2 of FIG. 8C is different from the light emitting element 30_1 of FIG. 8B in that the electrode layer 37 is positioned in an area of a first end portion 30S1 of a light emitting element 30_2, but the second semiconductor layer 32 is not positioned therein, and the thickness of the electrode layer 37 of FIG. 8C in the X-axis direction is formed to be thicker than that of the electrode layer 37 of FIG. 8B.

For example, although the inclination angles (e.g., the first interior angle θ1 or the second interior angle θ2) of end portions (e.g., opposite end portions) 30S1 and 30S2 of the light emitting element 30_2 of FIG. 8C are formed to be smaller, the thickness of the electrode layer 37 in the X-axis direction may be thick. Accordingly, although the first end portion 30S1 of the light emitting element 30_2 of FIG. 8C and the first end portion 30S1 of the light emitting element 30_1 of FIG. 8B have the same inclination angle, only the electrode layer 37 may be positioned in the area of the first end portion 30S1 of the light emitting element 30_2. Accordingly, the electrode layer 37 may form the first end portion 30S1 of the light emitting element 30_2.

In case that the light emitting element 30_2 of FIG. 8C is disposed between the first electrode 21 and the second electrode 22 on the substrate 11, the first contact electrode 26 may be in contact with the electrode layer 37 without being in contact with the second semiconductor layer 32 of the light emitting element 30_2 by sufficiently forming the thickness of the electrode layer 37 positioned in the first end portion 30S1 of the light emitting element 30_2 in the X-axis direction. Accordingly, as the electrode layer 37 is disposed between the first contact electrode 26 and the second semiconductor layer 32 in an end area of the light emitting element 30_2, resistance between the light emitting element 30_2 and the first contact electrode 26 may be reduced.

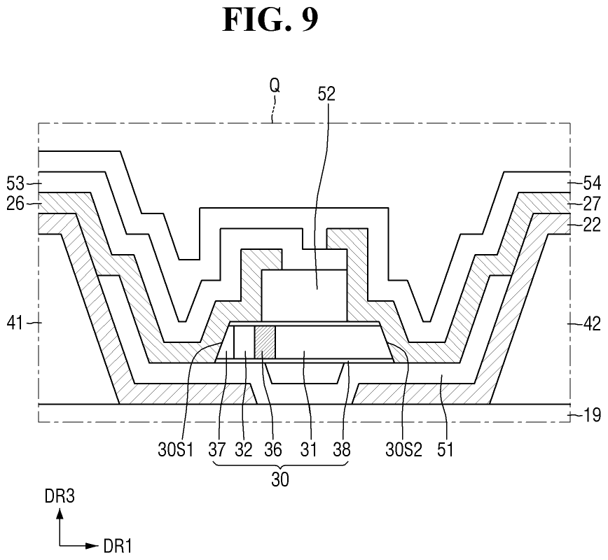

FIG. 9 is a schematic enlarged cross-sectional view of area Q of FIG. 3 in which the light emitting element 30 of FIG. 8A is disposed.

FIG. 9 is a schematic enlarged view of a portion of a cross section of the display device 10 in which the light emitting element 30 of FIG. 8A is disposed. Referring to FIG. 9 together with FIGS. 5 and 8A, the light emitting element 30 according to an embodiment may be disposed on the first insulating layer 51 between the first electrode 21 and the second electrode 22 as described above.

The first semiconductor layer 31, the active layer 36, the second semiconductor layer 32, and the electrode layer 37 included in the semiconductor core may be sequentially stacked in the first direction DR1. Each interface (or boundary surface) between the first semiconductor layer 31, the active layer 36, the second semiconductor layer 32, and the electrode layer 37 may be perpendicular to the first direction DR1.

The first end portion 3051 of the light emitting element 30 may be formed by the electrode layer 37, and the second end portion 30S2 thereof may be formed by the first semiconductor layer 31. In the embodiment, the first contact electrode 26 may be in contact with the first electrode 21 and the electrode layer 37, and the second contact electrode 27 may be in contact with the second electrode 22 and the first semiconductor layer 31.

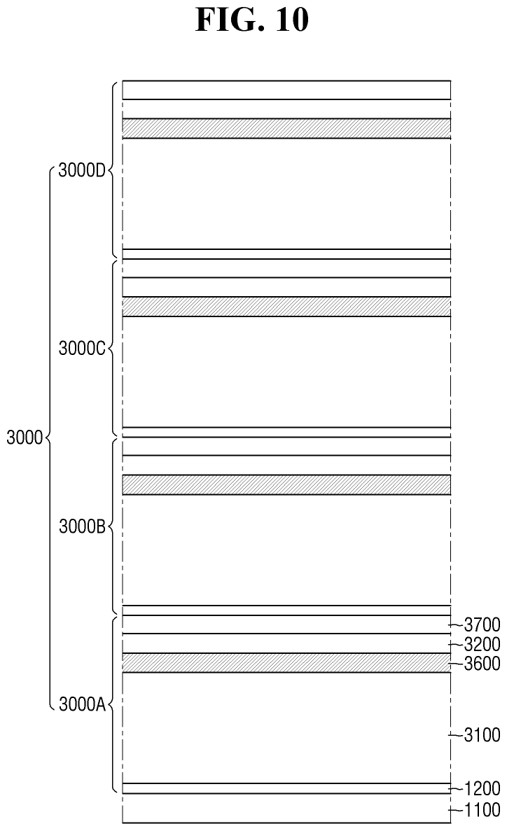

FIGS. 10 to 16 are schematic cross-sectional views illustrating a process of manufacturing the light emitting element 30 of FIG. 8A.

Referring to FIG. 10, semiconductor structures 3000 may be formed on a base substrate 1100.

For example, the base substrate 1100 may include a sapphire substrate (Al₂O₃) and a transparent substrate such as glass. However, the base substrate 1100 is not limited thereto, and may be formed as a conductive substrate such as GaN, SiC, ZnO, Si, GaP, and GaAs. Hereinafter, a case in which the base substrate 1100 is a sapphire substrate (Al₂O₃) will be described as an example.

Semiconductor layers may be formed on the base substrate 1100. The semiconductor layers grown by epitaxial deposition may be formed by growing a seed crystal. Here, a method of forming the semiconductor layers may be electron beam deposition, physical vapor deposition (PVD), chemical vapor deposition (CVD), plasma laser deposition (PLD), dual-type thermal evaporation, sputtering, metal organic chemical vapor deposition (MOCVD), or the like. For example, the semiconductor layers may be formed by metal-organic chemical vapor deposition (MOCVD). However, embodiments are not limited thereto.

A precursor material for forming the semiconductor layers is not limited within a range that may be selected for forming a target material. As an example, the precursor material may be a metal precursor including an alkyl group such as a methyl group or an ethyl group. For example, the precursor material may be a compound such as trimethyl gallium (Ga(CH₃)₃), trimethyl aluminum (Al(CH₃)₃), or triethyl phosphate ((C₂H₅)₃PO₄), but embodiments are not limited thereto. Hereinafter, a description for a method, a process condition, or the like for forming the semiconductor layers will be omitted, and a sequence of a method of manufacturing the light emitting element 30 or a stacked structure of the light emitting element 300 will be described in detail.

The semiconductor structure 3000 formed on the base substrate 1100 may include unit semiconductor structures 3000A, 3000B, 3000C, and 3000D. In an embodiment, the semiconductor structure 3000 may include a first unit semiconductor structure 3000A, a second unit semiconductor structure 3000B, a third unit semiconductor structure 3000C, and a fourth unit semiconductor structure 3000D. The first to fourth unit semiconductor structures 3000A, 3000B, 3000C, and 3000D may be sequentially stacked on the base substrate 1100. Each of the unit semiconductor structures 3000A, 3000B, 3000C, and 3000D may have the same stacked structure. Hereinafter, the stacked structure of the first unit semiconductor structure 3000A will be described, and the stacked structures of the second to fourth unit semiconductor structures 3000B, 3000C, and 3000D will be replaced with the description of the stacked structure of the first unit semiconductor structure 3000A.

The first unit semiconductor structure 3000A may be formed on the base substrate 1100. The first unit semiconductor structure 3000A may include a buffer material layer 1200, a first semiconductor material layer 3100, an active layer 3600, a second semiconductor material layer 3200, and an electrode material layer 3700 sequentially stacked on the base substrate 1100.

The buffer material layer 1200 may reduce a difference in lattice constant between the first semiconductor material layer 3100 and the base substrate 1100. For example, the buffer material layer 1200 may protect the first semiconductor material layer 3100 in a process of cutting the semiconductor rod to manufacture the light emitting element 30, which will be described below. The buffer material layer 1200 may include an undoped semiconductor, and may include a material that is substantially the same as that of the first semiconductor material layer 3100, but may not be doped with an n-type dopant or a p-type dopant. In an embodiment, the buffer material layer 1200 may be made of at least one of undoped InAlGaN, GaN, AlGaN, InGaN, AlN, and InN, but embodiments are not limited thereto.

Material layers disposed on the buffer material layer 1200, for example, the first semiconductor material layer 3100, the active layer 3600, the second semiconductor material layer 3200, and the electrode material layer 3700 may be formed by performing the typical process as described above. Each of the first semiconductor material layer 3100, the active layer 3600, the second semiconductor material layer 3200, and the electrode material layer 3700 included in the first unit semiconductor structure 3000A may correspond to each layer of the light emitting element 30 according to an embodiment. For example, the first semiconductor material layer 3100 and the first semiconductor layer 31 of the light emitting element 30 may include the same material. The active layer 3600 and the active layer 36 of the light emitting element 30 may include the same material. The second semiconductor material layer 3200 and the second semiconductor layer 32 of the light emitting element 30 may include the same material. The electrode material layer 3700 and the electrode layer 37 of the light emitting element 30 may include the same material.

A buffer material layer 1200 of the second unit semiconductor structure 3000B may be formed on the electrode material layer 3700 of the first unit semiconductor structure 3000A.

For example, a buffer material layer 1200 of the third unit semiconductor structure 3000C may be formed on an electrode material layer 3700 of the second unit semiconductor structure 3000B.

For example, a buffer material layer 1200 of the fourth unit semiconductor structure 3000D may be formed on an electrode material layer 3700 of the third unit semiconductor structure 3000C.

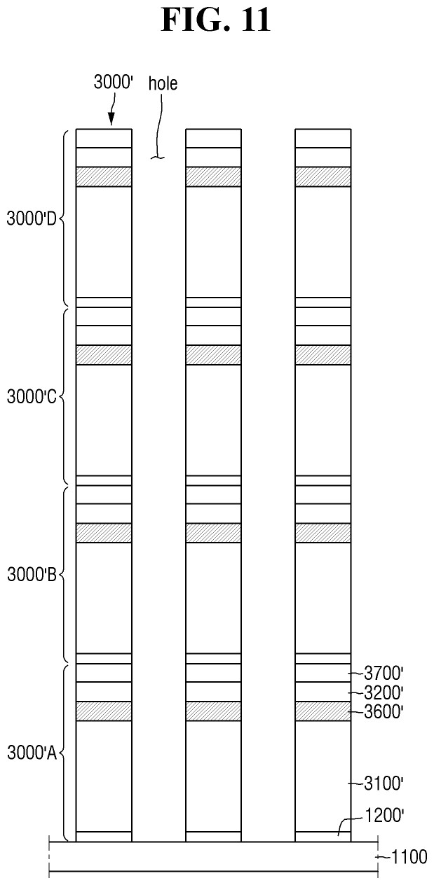

Referring to FIG. 11, the semiconductor structure 3000 is vertically etched to form semiconductor crystals 3000′ spaced apart from each other. The semiconductor crystal 3000′ may include first to fourth unit semiconductor crystals 3000′A, 3000′B, 3000′C, and 3000′D formed by etching the first to fourth unit semiconductor structures 3000A, 3000B, 3000C, and 3000D, respectively.

A vertical direction in which the semiconductor structure 3000 is etched may be substantially parallel to a stacking direction of the material layers included in the semiconductor structure 3000. The semiconductor structure 3000 may be etched by a typical method. For example, the semiconductor structure 3000 may be etched by a method of forming an etch mask layer on the semiconductor structure 3000 and etching the semiconductor structure 3000 along the etch mask layer in a direction perpendicular to a surface of the base substrate 1110. A separation hole may be formed between the semiconductor crystals 3000′ by the etching process.

For example, the process of etching the semiconductor structure 3000 may be a dry etching method, a wet etching method, a reactive ion etching (RIE) method, an inductively coupled plasma reactive ion etching (ICP-RIE) method, or the like. As anisotropic etching is possible in the dry etching method, the dry etching method may be suitable for vertical etching. In case that the above-described etching method is used, an etching etchant may be Cl₂ or O₂. However, embodiments are not limited thereto.

In some embodiments, the semiconductor structure 3000 may be etched by mixing the dry etching method and the wet etching method. For example, after etching in a depth direction is first performed by the dry etching method, an etched sidewall may be placed on a plane perpendicular to a surface by the wet etching method, which is isotropic etching.

For example, an element rod including an insulating film 3800′ surrounding (e.g., partially surrounding) an outer surface of the semiconductor crystal 3000′ may be formed.

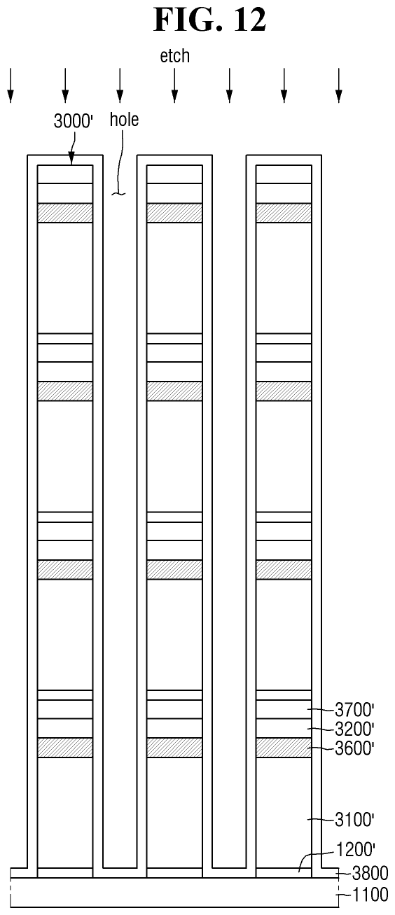

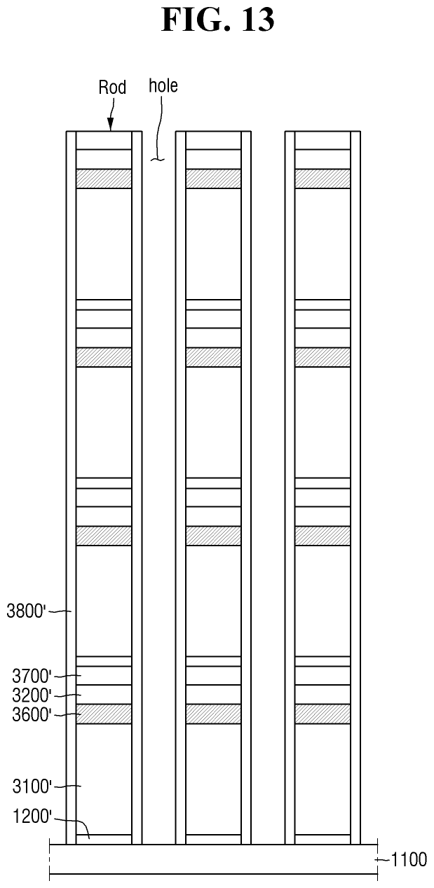

Referring to FIGS. 12 and 13, the element rod may be formed by entirely forming the insulating material layer 3800 on the semiconductor crystal 3000′ and removing (e.g., partially removing) the insulating material layer 3800 so that an upper surface of the electrode material layer 3700′ of the fourth unit semiconductor crystal 3000′D is exposed.

For example, referring to FIG. 12, the insulating material layer 3800 may be formed (e.g., entirely formed) on the semiconductor crystal 3000′. The insulating material layer 3800 may also be formed on side surfaces and an upper surface of the semiconductor crystal 3000′ and on the base substrate 1100 exposed in the separation hole of the semiconductor crystal 3000′.

The insulation material layer 3800 may be an insulating material formed on the outer surface of the semiconductor crystal 3000′, and may be formed by a method of applying an insulating material on the outer surface of the vertically etched semiconductor crystal 3000′ or by a method of immersing the outer surface of the vertically etched semiconductor crystal 3000′ in the insulating material. However, embodiments are not limited thereto. As an example, the insulation material layer 3800 may be formed by atomic layer deposition (ALD).

Referring to FIG. 13, the insulating material layer 3800 may be removed (e.g., partially removed) to expose the upper surface of the electrode material layer 3700′ of the fourth unit semiconductor crystal 3000′. In a process of removing (e.g., partially removing) the insulation film 3800′, a process such as dry etching or etch-back, which is anisotropic etching, may be performed.

The insulating film 3800′ of the element rod may partially or entirely surround the side surfaces of the semiconductor crystal 3000′. For example, the element rod may include a structure in which the insulating film 3800′ covers (e.g., completely covers) the side surfaces of the semiconductor crystal 3000′.

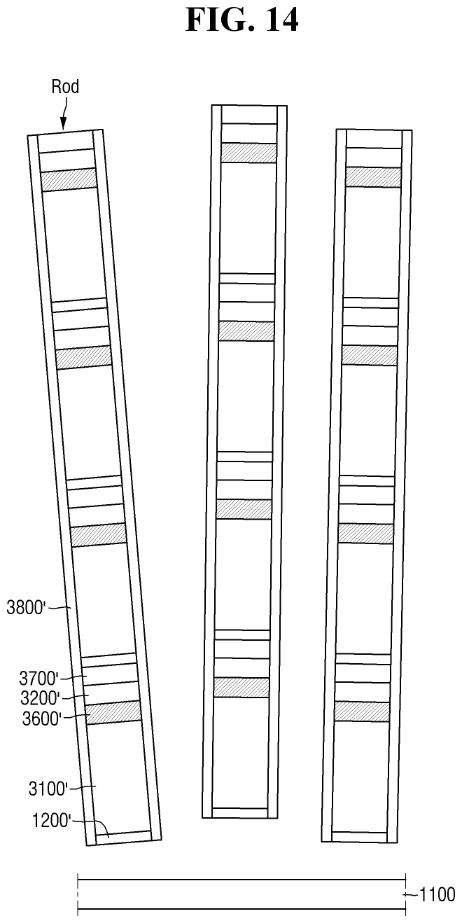

Referring to FIG. 14, the element rod, on which the insulating film 3800′ is formed, may be separated from the base substrate 1100. A method of separating the element rod from the base substrate 1100 is not limited. The process of separating the element rod from the base substrate 1100 may be performed by a physical separation method or a chemical separation method.

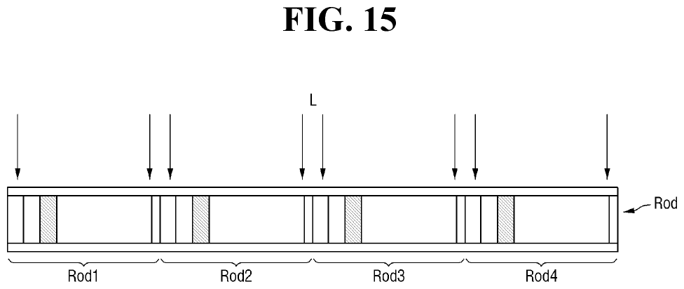

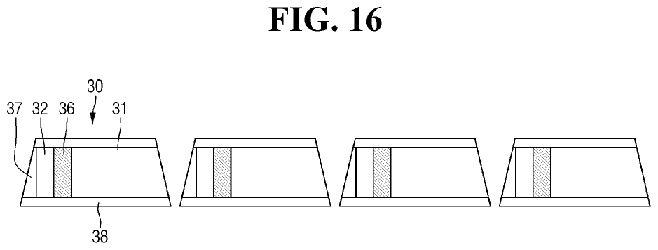

Referring to FIGS. 15 and 16, light emitting elements 30 may be manufactured by cutting the element rod.

Referring to FIG. 15, the element rod may include unit element rods. The unit element rods may include a first unit element rod Rod1, a second unit element rod Rod2, a third unit element rod Rod3, and a fourth unit element rod Rod4. The first to fourth unit element rods Rod1, Rod2, Rod3, and Rod4 may be structures corresponding to the first to fourth unit semiconductor structures 3000A, 3000B, 3000C, and 3000D, respectively.

The light emitting elements 30 having end portions (e.g., opposite end portions) inclined as illustrated in FIG. 16 are manufactured by cutting between the first to fourth unit elements rods Rod1, Rod2, Rod3, and Rod4. A method of cutting between the first to fourth unit element rods Rod1, Rod2, Rod3, and Rod4 is not limited. A method of cutting the buffer material layer 1200′ and the electrode material layer 3700′ disposed between the unit element rods Rod1, Rod2, Rod3, and Rod4 may be performed by a physical cutting method or a chemical cutting method. For example, end portions (e.g., opposite end portions) of the buffer material layer 1200′ and the electrode material layer 3700′ disposed between the unit element rods Rod1, Rod2, Rod3, and Rod4 may be cut to be inclined using a laser or a drill. It is illustrated in the drawing a process of separating each of the unit element rods Rod1, Rod2, Rod3, and Rod4 by irradiating a laser beam L using a laser to the buffer material layer 1200′ and the electrode material layer 3700′ disposed between the unit element rods Rod1, Rod2, Rod3, and Rod4 and manufacturing the light emitting element 30 having an end and another end inclined.

The light emitting element 30 according to an embodiment may be manufactured by the processes described above. The light emitting element 30 manufactured in this way may have the respective material layers stacked in the extension direction of the light emitting element 30, for example, the first semiconductor layer 31, the active layer 36, the second semiconductor layer 32, and the electrode layer 37. The interface (or boundary surface) between the respective material layers may be perpendicular to the extension direction of the light emitting element 30. For example, the light emitting elements 30 in which end portions (e.g., opposite end portions) of the light emitting element 30 are inclined with respect to the extension direction of the light emitting element 30 may be manufactured by cutting between the first to fourth unit element rods Rod1, Rod2, Rod3, and Rod4.

Hereinafter, an embodiment will be described. In the following embodiment, an overlapping description for the same components as those described above will be omitted or simplified, and components different from those described above will be described for descriptive convenience.

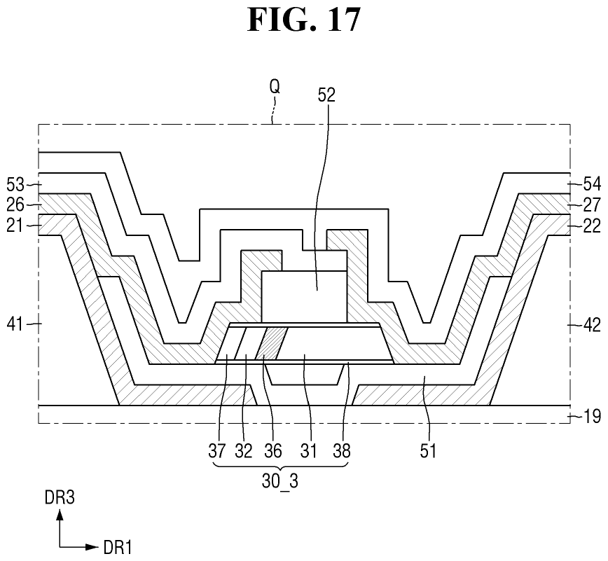

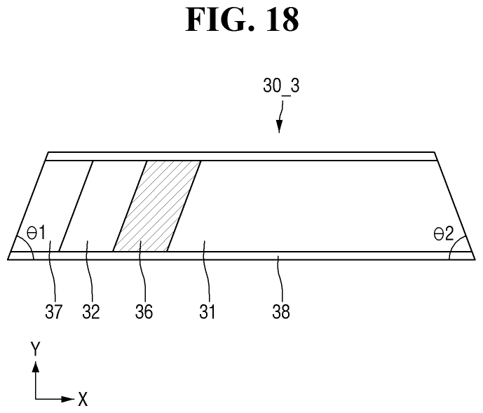

FIG. 17 is a schematic cross-sectional view illustrating another example of the light emitting element 30 taken along the line VIII-VIII′ of FIG. 5. FIG. 18 is a schematic enlarged cross-sectional view of area Q of FIG. 3 in which the light emitting element of FIG. 17 is disposed.

Referring to FIGS. 17 and 18, a light emitting element 30_3 of FIGS. 17 and 18 is different from the light emitting element 30 of FIGS. 8A and 9 in that layers constituting a semiconductor core is inclined with respect to the X-axis direction, which is an extension direction of the light emitting element 30_3.

For example, the semiconductor core of the light emitting element 30_3 may include a first semiconductor layer 31, an active layer 36, a second semiconductor layer 32, and an electrode layer 37 sequentially disposed in the X-axis direction. Each interface (or boundary surface) between the first semiconductor layer 31, the active layer 36, the second semiconductor layer 32, and the electrode layer 37 may be inclined with respect to the first direction. The light emitting element 30_3 of FIGS. 17 and 18 may be formed by a process of manufacturing the light emitting element 30_3.

Hereinafter, a method of manufacturing the light emitting element 30_3 of FIG. 17 will be schematically described.

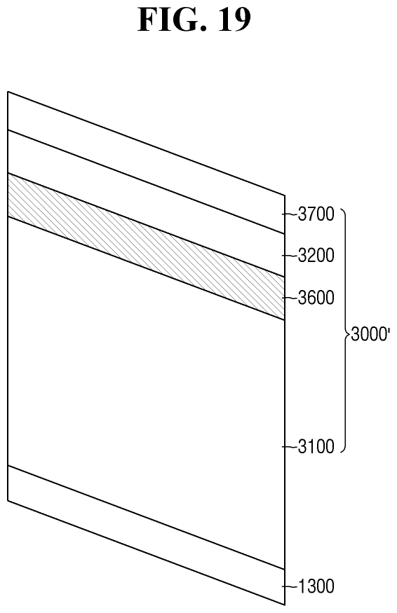

FIGS. 19 to 23 are schematic cross-sectional views illustrating processes of manufacturing the light emitting element 30_3 of FIG. 17.

First, referring to FIG. 19, a structure in which the first semiconductor material layer 3100, the active layer 3600, the second semiconductor material layer 3200, and the electrode material layer 3700 are sequentially stacked on a lower substrate 1300 is formed.

For example, the lower substrate 1300 may include layers. The lower substrate 1300 may include the above-described base substrate and the buffer material layer disposed on the base substrate. For example, the lower substrate 1300 may have a structure in which a sapphire substrate (Al₂O₃) and a transparent substrate such as glass, and the buffer material layer disposed on the transparent substrate are stacked.

The lower substrate 1300 may be inclined. As the lower substrate 1300 is inclined, material layers constituting a semiconductor structure to be described below may be stacked to be inclined with respect to a surface.

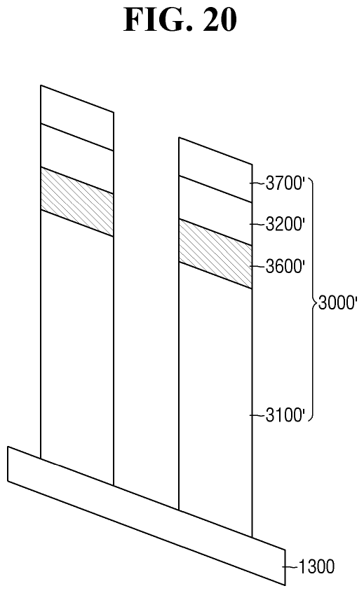

Referring to FIG. 20, the semiconductor structure 3000 may be vertically etched to form semiconductor crystals 3000′ spaced apart from each other.

A vertical direction in which the semiconductor structure 3000 is etched may be substantially parallel to an extension direction of the semiconductor structure 3000. For example, the vertical direction in which the semiconductor structure 3000 is etched may be inclined at an angle with respect to the stacking direction of the material layers included in the semiconductor structure 3000. As described above with reference to FIG. 19, as the semiconductor layers are formed on the lower substrate 1300 inclined at the angle with respect to a surface, an inclined surface of each semiconductor layer may be inclined with respect to the vertical direction in which the semiconductor structure 3000 is etched.

The semiconductor structure 3000 may be etched by a typical method. For example, the semiconductor structure 3000 may be etched by a method of forming an etch mask layer on the semiconductor structure 3000 and etching the semiconductor structure 3000 along the etch mask layer in a direction perpendicular to a surface of the base substrate 1110.

For example, an element rod including an insulating film 3800′ surrounding (e.g., partially surrounding) an outer surface of the semiconductor crystal 3000′ may be formed.

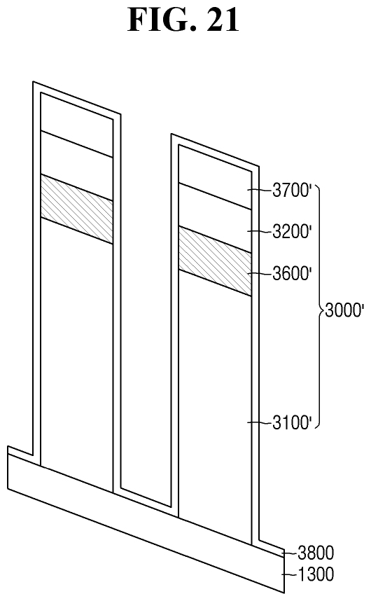

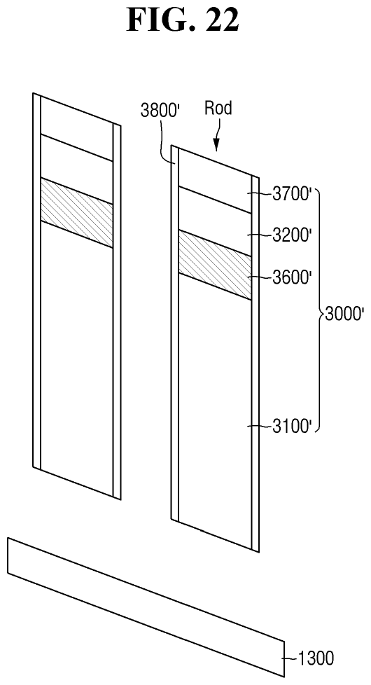

Referring to FIGS. 21 and 22, the element rod may be formed by entirely forming the insulating material layer 3800 on the semiconductor crystal 3000′ and removing (e.g., partially removing) the insulating material layer 3800 so that an upper surface of the electrode material layer 3700′ of the semiconductor crystal 3000′ is exposed.

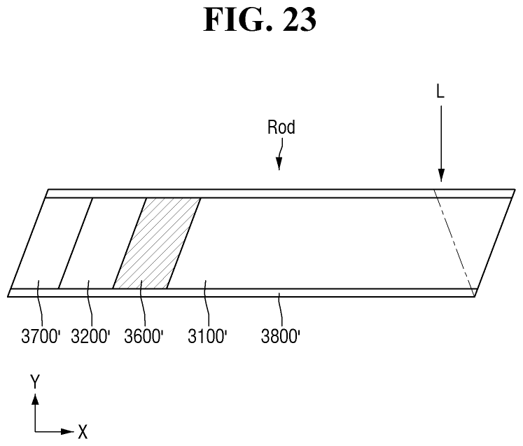

Referring to FIG. 23, the light emitting element 30_3 of FIG. 18 may be manufactured by cutting the first semiconductor material layer 3100′ of the element rod. For example, an end at which the first semiconductor material layer 3100′ is disposed may be cut to be inclined toward another end at which the electrode material layer 3700′ is disposed. The cutting method may be performed by a physical cutting method or a chemical cutting method as described above. For example, the light emitting element 30_3 may be manufactured by irradiating a laser beam L to an end portion of the first semiconductor material layer 3100′ of the element rod.

In concluding the detailed description, those skilled in the art will appreciate that many variations and modifications can be made to the embodiments without substantially departing from the principles of the invention. Therefore, the disclosed embodiments of the invention are used in a generic and descriptive sense only and not for purposes of limitation.

1. A display device comprising:
a substrate;
a first electrode disposed on the substrate;
a second electrode disposed on the substrate and spaced apart from the first electrode;
a first insulating layer disposed between the first electrode and the second electrode and covering at least a portion of the first electrode and the second electrode; and
a light emitting element disposed on the first insulating layer between the first electrode and the second electrode and extending in a first direction, wherein
the light emitting element includes:
a first side extending in the first direction,
a second side extending in the first direction and opposite the first side,
a first lateral side connecting a first end portion of the first side and a first end portion of the second side to each other, and
a second lateral side connecting a second end portion of the first side and a second end portion of the second side to each other,
a first interior angle formed by the first side and the first lateral side is an acute angle, and
a second interior angle formed by the first side and the second lateral side is an acute angle.

2. The display device of claim 1, wherein
the first interior angle is about 75° or less, and
the second interior angle is about 75° or less.

3. The display device of claim 2, wherein the first interior angle and the second interior angle are substantially equal to each other.

4. The display device of claim 1, wherein the light emitting element includes:
a semiconductor core extending in the first direction, and
an insulating layer surrounding a side surface of the semiconductor core.

5. The display device of claim 4, wherein the semiconductor core includes:
a first semiconductor layer,
a second semiconductor layer disposed on the first semiconductor layer, and
an active layer disposed between the first semiconductor layer and the second semiconductor layer.

6. The display device of claim 5, wherein
the first semiconductor layer, the active layer, and the second semiconductor layer are sequentially disposed in the first direction, and
each boundary surface between the first semiconductor layer, the active layer, and the second semiconductor layer is substantially perpendicular to the first direction.

7. The display device of claim 5, wherein
the first semiconductor layer, the active layer, and the second semiconductor layer are sequentially disposed in the first direction, and
each boundary surface between the first semiconductor layer, the active layer, and the second semiconductor layer is inclined with respect to the first direction.

8. The display device of claim 1, wherein the first side of the light emitting element is at least partially in contact with an upper surface of the first insulating layer.

9. The display device of claim 8, wherein
the upper surface of the first insulating layer in contact with the light emitting element and the first side of the light emitting element are inclined at an acute angle, and
the upper surface of the first insulating layer in contact with the light emitting element and the second side of the light emitting element are inclined at an acute angle.

10. The display device of claim 1, further comprising:
a second insulating layer disposed on the light emitting element and exposing the first lateral side of the light emitting element and the second lateral side of the light emitting element.

11. The display device of claim 10, wherein the second insulating layer does not overlap the first lateral side of the light emitting element and the second lateral side of the light emitting element.

12. The display device of claim 1, further comprising:
a first contact electrode and a second contact electrode disposed on the first insulating layer and spaced apart from each other, wherein
the first contact electrode is in contact with the first electrode and the first lateral side of the light emitting element, and
the second contact electrode is in contact with the second electrode and the second lateral side of the light emitting element.

13. A display device comprising:
a substrate;
a first electrode disposed on the substrate;
a second electrode disposed on the substrate and spaced apart from the first electrode;
a first insulating layer disposed between the first electrode and the second electrode and covering at least a portion of the first electrode and the second electrode; and
a light emitting element disposed on the first insulating layer between the first electrode and the second electrode and extending in a first direction,
wherein
the light emitting element includes:
a first end portion electrically connected to the first electrode, and
a second end portion electrically connected to the second electrode, and
the first end portion and the second end portion are inclined with respect to the first direction.

14. The display device of claim 13, wherein
the first direction is substantially parallel to an upper surface of the substrate,
an inclined surface of the first end portion of the light emitting element is inclined in a first diagonal direction with respect to the upper surface of the substrate,
an inclined surface of the second end portion of the light emitting element is inclined in a second diagonal direction with respect to the upper surface of the substrate, and
the first and second diagonal directions in which the inclined surface of the first end portion of the light emitting element and the inclined surface of the second end portion of the light emitting element are inclined with respect to the upper surface of the substrate are opposite to each other.

15. The display device of claim 14, wherein the inclined surface of the first end portion of the light emitting element and the inclined surface of the second end portion of the light emitting element are in a symmetrical relationship with respect to a cut surface crossing a central portion of the light emitting element in a direction perpendicular to the first direction.

16. The display device of claim 13, further comprising:
a first contact electrode and a second contact electrode disposed on the first insulating layer and spaced apart from each other, wherein
the first contact electrode is in contact with the first electrode and the first end portion of the light emitting element, and
the second contact electrode is in contact with the second electrode and the second end portion of the light emitting element.

17. The display device of claim 13, further comprising:
a second insulating layer disposed on the light emitting element and not overlapping the first end portion of the light emitting element and the second end portion of the light emitting element.

18. The display device of claim 13, wherein an inclined extension surface of the first end portion of the light emitting element and an inclined extension surface of the second end portion of the light emitting element are each inclined to be closer to each other as moving in a second direction perpendicular to the first direction.

19. The display device of claim 18, wherein the second direction is a thickness direction of the display device.

20. A light emitting element comprising
a first side extending in a first direction;
a second side extending in the first direction and opposite to the first side;
a first lateral side connecting a first end portion of the first side and a first end portion of the second side to each other; and
a second lateral side connecting a second end portion of the first side and a second end portion of the second side to each other, wherein
a first interior angle formed by the first side and the first lateral side is an acute angle, and
a second interior angle formed by the first side and the second lateral side is an acute angle.

21. The light emitting element of claim 20, wherein the light emitting element includes:
a semiconductor core extending in the first direction, and
an insulating layer surrounding a side surface of the semiconductor core.

22. The light emitting element of claim 21, wherein the semiconductor core includes:
a first semiconductor layer,
a second semiconductor layer disposed on the first semiconductor layer, and
an active layer disposed between the first semiconductor layer and the second semiconductor layer.

23. The light emitting element of claim 22, wherein
the first semiconductor layer, the active layer, and the second semiconductor layer are sequentially disposed in the first direction, and
each boundary surface between the first semiconductor layer, the active layer, and the second semiconductor layer is substantially perpendicular to the first direction.

24. The light emitting element of claim 22, wherein
the first semiconductor layer, the active layer, and the second semiconductor layer are sequentially disposed in the first direction, and
each boundary surface between the first semiconductor layer, the active layer, and the second semiconductor layer is inclined with respect to the first direction.
